(19) United States
(12) Patent Application Publication
(10) Pub. No.: US 2012/0299052 A1
(43) Pub. Date: Nov. 29, 2012

(54) SEMICONDUCTOR LIGHT-EMITTING DEVICE, METHOD FOR MANUFACTURING SEMICONDUCTOR LIGHT-EMITTING DEVICE, AND OPTICAL DEVICE

(75) Inventors: Nobuhiko Hayashi, Osaka-shi (JP); Masayuki Hata, Takatsuki-shi (JP)

(73) Assignee: SANYO ELECTRIC CO., LTD., Moriguch-shi (JP)

(21) Appl. No.: 13/576,954

(22) PCT Filed: Feb. 4, 2011
(86) PCT No.: PCT/JP2011/052356

§ 371 Date: Aug. 3, 2012

(30) Foreign Application Priority Data
Feb. 4, 2010 (JP) 2010-022675
May 14, 2010 (JP) 2010-111661

(51) Int. Cl. H01L 33/48

(52) U.S. Cl. 257/99; 438/26; 257/E33.066

(57) ABSTRACT

A semiconductor light-emitting device capable of inhibiting a semiconductor light-emitting element from deterioration and capable of inhibiting the size of a package from enlargement is obtained. The semiconductor light-emitting device includes a semiconductor light-emitting element and a package sealing the semiconductor light-emitting element. The package includes a base portion mounted with the semiconductor light-emitting element and a cap portion mounted on the base portion for covering the semiconductor light-emitting element. At least either one of the base portion and the cap portion is made of a mixture of resin and a gas absorbent.

### TECHNICAL FIELD

The present invention relates to a semiconductor light-emitting device, a method for manufacturing a semiconductor light-emitting device and an optical device, and more particularly, it relates to a semiconductor light-emitting device including a base portion mounted with a semiconductor light-emitting element and a cap portion covering the semiconductor light-emitting element, a method for manufacturing a semiconductor light-emitting device and an optical device.

### BACKGROUND TECHNIQUE

In general, a semiconductor light-emitting element is widely employed as a light source for an optical disk system or an optical communication system. For example, an infrared semiconductor laser element emitting a laser beam of about 780 nm is put into practice as a light source for playing back a CD. A red semiconductor laser element emitting a laser beam of about 650 nm is put into practice as a light source for recording/playing back a DVD. A blue-violet semiconductor laser element emitting a laser beam of about 405 nm is put into practice as a light source for a Blu-ray disk.

A semiconductor light-emitting device including a package having a base portion mounted with a semiconductor light-emitting element and a cap portion covering the semiconductor light-emitting element in order to implement such a light source device is known in general. Such a semiconductor light-emitting device is disclosed in Japanese Patent Laying-Open No. 9-205251, for example.

In Japanese Patent Laying-Open No. 9-205251, there is disclosed a plastic molding device of a semiconductor laser including a header (base portion) formed by a resin-molded product provided with a flange surface, a semiconductor laser element mounted through an Si submount (base) on an element placement portion integrally formed on the header and a transparent cap of resin covering the periphery of the semiconductor laser element. In the plastic molding device of the semiconductor laser described in this Japanese Patent Laying-Open No. 9-205251, an opening end portion of the transparent cap is bonded to the flange surface of the header through an adhesive containing epoxy-based material, whereby the semiconductor laser element is airtightly sealed in a package surrounded by the header and the transparent cap.

A semiconductor light-emitting device in which absorbent employing activated carbon, zeolite or the like is separately set in a package sealing a semiconductor light-emitting element is also known. Such a semiconductor light-emitting device is disclosed in Japanese Patent Laying-Open No. 2008-147205, for example.

### PRIOR ART

### Patent Documents

Patent Document 1: Japanese Patent Laying-Open No. 9-205251
Patent Document 2: Japanese Patent Laying-Open No. 2008-147205

### SUMMARY OF THE INVENTION

### Problems to be Solved by the Invention

In the plastic molding device of the semiconductor laser described in Japanese Patent Laying-Open No. 9-205251, however, the header and the transparent cap are made of resin material, and hence it is conceivable that organic gas fills up the package in a case where volatile organic gas is generated from the resin materials. Further, the epoxy-based adhesive is employed for bonding the header to the transparent cap, and hence it is conceivable that a large quantity of organic gas is generated also from this adhesive. In a case of operating a blue-violet semiconductor laser element in a state where the large quantity of organic gas fills up the package, there is an apprehension that the organic gas is excited by a laser beam emitted from a laser-emitting facet and decomposed in the vicinity of the laser-emitting facet to form an incrustation on the laser-emitting facet. In this case, there is such an inconvenience that the incrustation absorbs the laser beam to cause temperature rise on the laser-emitting facet and the laser element deteriorates.

In the semiconductor light-emitting device disclosed in Japanese Patent Laying-Open No. 2008-147205, the absorbent is set in a limited space in the package, and hence it is necessary to constitute the internal volume of the package on a large scale in response to the magnitude of the absorbent. Therefore, there is such a problem that the size of the semiconductor light-emitting device enlarges.

The present invention has been proposed in order to solve the aforementioned problems, and an object of the present invention is to provide a semiconductor light-emitting device capable of inhibiting a semiconductor light-emitting element from deterioration and capable of inhibiting the size of a package from enlargement, a method for manufacturing a semiconductor light-emitting device and an optical device.

### Means for Solving the Problems

A semiconductor light-emitting device according to a first aspect of the present invention includes a semiconductor light-emitting element and a package sealing the semiconductor light-emitting element, while the package includes a base portion mounted with the semiconductor light-emitting element and a cap portion mounted on the base portion for covering the semiconductor light-emitting element, and at least either one of the base portion and the cap portion is made of a mixture of resin and a gas absorbent.

In the semiconductor light-emitting device according to the first aspect of the present invention, as hereinabove described, at least either one of the base portion and the cap portion is made of the mixture of the resin and the gas absorbent, whereby volatile organic gas generated from the resin can be absorbed by the gas absorbent mixed into the resin also in the case of employing the resin as the material constituting at least either one of the base portion and the cap portion. Thus, the organic gas can be inhibited from filling up the package sealing the semiconductor light-emitting element, whereby the same can be inhibited from being excited or decomposed by light emitted from the semiconductor light-emitting element and being formed as a solid incrustation on a light-emitting facet of the semiconductor light-emitting element. Consequently, the semiconductor light-emitting element can be inhibited from deterioration.

Further, the gas absorbent is mixed into at least either one of the base portion and the cap portion, whereby no member containing the gas absorbent may be separately set in the package. Thus, the internal volume of the package may not be enlarged, whereby the size of the package can be inhibited from enlargement.

Preferably in the aforementioned semiconductor light-emitting device according to the first aspect, the cap portion has a light transmission portion, made of the mixture, through which light emitted from the semiconductor light-emitting element is transmitted toward the exterior, the resin has translucency, and the gas absorbent is mixed into the mixture constituting the cap portion other than the light transmission portion. When forming the semiconductor light-emitting device in this manner, the cap portion having the light transmission portion can be formed by using the same resin having transparency, whereby the cap portion can be easily manufactured, while the structure of the cap portion can be simplified. Further, the gas absorbent is mixed into the resin constituting the cap portion other than the light transmission portion, whereby neither light absorption nor light scattering by the gas absorbent takes place in the light transmission portion. Thus, outgoing light can be reliably emitted from the light transmission portion, while organic gas generated from the resin of the cap portion including the light transmission portion can be inhibited from filling up the package.

Preferably in the aforementioned semiconductor light-emitting device according to the first aspect, the gas absorbent is at least any one of synthetic zeolite, silica gel and activated carbon. When forming the semiconductor light-emitting device in this manner, organic gas generated from the resin can be sufficiently absorbed, while at least either one of the base portion and the cap portion can be easily prepared from the mixture of the resin and the gas absorbent consisting of the aforementioned material.

Preferably in the aforementioned semiconductor light-emitting device according to the first aspect, a gas barrier layer is formed on the surface of at least either one of the base portion and the cap portion made of the mixture. In the present invention, the gas barrier layer denotes a layer made of material having lower gas permeability than the resin constituting the base portion and the cap portion. When forming the semiconductor light-emitting device in this manner, low-molecular siloxane, volatile organic gas or the like present in the exterior (in the atmosphere) of the semiconductor light-emitting device can be inhibited from permeating the material for the base portion or the cap portion and penetrating into the package, whereby deterioration of the semiconductor light-emitting element can be further suppressed.

Preferably, the aforementioned semiconductor light-emitting device according to the first aspect further includes a plurality of lead terminals mounted on the base portion and arranged on an identical plane and a heat radiation portion formed integrally with an element placement portion on which the semiconductor light-emitting element is placed, and the heat radiation portion is arranged outside the plurality of lead terminals. In other words, a lead terminal positioned on the outermost side among the plurality of lead terminals is held and arranged between the heat radiation portion and other lead terminals in a direction parallel to the plane on which the plurality of lead terminals are arranged, and the heat radiation portion is not arranged between the plurality of lead terminals. When forming the semiconductor light-emitting device in this manner, the heat radiation portion radiating heat generated from the semiconductor light-emitting element may not be arranged in a limited space between a first lead terminal and a second lead terminal, whereby the surface area of the heat radiation portion can be enlarged. Thus, heat radiation characteristics in the heat radiation portion can be improved.

Preferably in this case, the heat radiation portion is arranged on the identical plane. When forming the semiconductor light-emitting device in this manner, each lead terminal and the heat radiation portion can be easily formed by a lead frame or the like, for example. Also when mounting this semiconductor light-emitting device on a housing of an optical pickup device or the like, for example, the heat radiation portion and the housing can be easily fixed to each other, whereby heat generated by the semiconductor light-emitting element can be easily radiated to the housing.

Preferably in the aforementioned structure further including the heat radiation portion, the heat radiation portion and the element placement portion are connected with each other by a connection portion extending from a front surface side toward a rear surface side of the base portion, and a connection region between the heat radiation portion and the connection portion is arranged on the rear surface side of the base portion. When forming the semiconductor light-emitting device in this manner, a heat radiation area can be sufficiently ensured, whereby heat generated by a semiconductor laser element can be sufficiently radiated through the heat radiation portion. Further, the heat radiation portion and the connection portion are connected with each other on the rear surface of the base portion, whereby a cap for sealing the semiconductor laser element can be mounted on the front surface side of the base portion without interfering with the heat radiation portion.

Preferably in the aforementioned structure in which the connection region is arranged on the rear surface side of the base portion, the connection region is at least partially exposed from the rear surface of the base portion. When forming the semiconductor light-emitting device in this manner, the heat radiation portion can be easily exposed toward the exterior of the base portion, whereby heat radiation characteristics in the heat radiation portion can be improved.

Preferably in the aforementioned structure in which the connection region is arranged on the rear surface side of the base portion, the heat radiation portion is arranged outside the cap portion. When forming the semiconductor light-emitting device in this manner, the semiconductor laser element can be easily sealed in a state maintaining heat radiation properties.

Preferably in the aforementioned structure further including the heat radiation portion, the heat radiation portion is arranged on outside the plurality of lead terminals at least on one side of both sides of the base portion. In other words, the heat radiation portion is held and arranged between a one side surface of the base portion and a lead terminal positioned on the outermost side among the plurality of lead terminals, and the heat radiation portion is not arranged between the plurality of lead terminals. When forming the semiconductor light-emitting device in this manner, heat generated by the semiconductor light-emitting element can be radiated from the heat radiation portion to the exterior through the connection portion even if the semiconductor light-emitting device includes the heat radiation portion only on the one side portion of the base portion. Thus, the width of the semiconductor light-emitting device can be easily reduced.

Preferably in the aforementioned structure further including the heat radiation portion, the lead terminals include a first lead terminal mounted on the rear surface of the base portion, and the element placement portion is formed integrally with the first lead terminal. When forming the semiconductor light-emitting device in this manner, the first lead terminal can be made to also play the role of a heat radiation function. Thus, heat radiation properties of a semiconductor laser device can be further improved.

Preferably in the aforementioned structure further including the heat radiation portion, the lead terminals include a second lead terminal mounted on the rear surface of the base portion, and the element placement portion and the second lead terminal are arranged on different planes. When forming the semiconductor light-emitting device in this manner, the number of the lead terminals can be easily increased without reducing the width of the lead terminals. Further, the width (cross section) of the connection portion can be properly ensured also in a case of increasing the number of the lead terminals, whereby heat radiation (heat transfer) characteristics can be inhibited from lowering when radiating heat from the element placement portion to the heat radiation portion through the connection portion.

Preferably in the aforementioned structure further including the heat radiation portion, at least a part of the connection portion or the heat radiation portion is bent. When forming the semiconductor light-emitting device in this manner, the surface area of the heat radiation portion can be further enlarged. Thus, the heat radiation portion can be extended and arranged also in the bent direction, whereby heat radiation characteristics can be further improved.

Preferably in this case, at least a part of the connection portion or the heat radiation portion is bent in a direction parallel to the rear surface of the base portion. When forming the semiconductor light-emitting device in this manner, the heat radiation portion after the bending can be extended in the direction parallel to the rear surface of the base portion, whereby heat radiation characteristics can be effectively improved while inhibiting the dimensions of the base portion mounted with the lead terminals from enlargement.

Preferably in the aforementioned structure further including the heat radiation portion, the width of the heat radiation portion is larger than the width of the lead terminals. When forming the semiconductor light-emitting device in this manner, heat generated by the semiconductor light-emitting element can be transmitted (thermally conducted) to the heat radiation portion in preference to the lead terminals. Thus, heat of the semiconductor light-emitting element can be reliably radiated to the exterior of the semiconductor light-emitting device through the heat radiation portion.

Preferably in the aforementioned semiconductor light-emitting device according to the first aspect, the resin has elasticity, and the base portion and the cap portion so engage with each other that the semiconductor light-emitting element is sealed. When forming the semiconductor light-emitting device in this manner, the base portion can be easily brought into close contact with the cap portion, whereby the interior of the package can be easily sealed. In other words, no adhesive or the like for performing the sealing may be further used, whereby generation of organic gas can be suppressed.

Preferably in the aforementioned structure in which the base portion and the cap portion engage with each other, the base portion and the cap portion are both made of mixtures of the resin and the gas absorbent, and the ratio of the gas absorbent mixed into the resin constituting the cap portion with respect to the resin is smaller than the ratio of the gas absorbent mixed into the resin constituting the base portion with respect to the resin. When forming the semiconductor light-emitting device in this manner, elasticity resulting from the resin in the cap portion can be easily maintained, whereby the base portion and the cap portion can be reliably engaged with each other.

Preferably in the aforementioned structure in which the base portion and the cap portion engage with each other, the base portion has an outer peripheral surface tapering from the rear surface side toward the front surface side of the base portion, and the cap portion engages with the tapering outer peripheral surface of the base portion. When forming the semiconductor light-emitting device in this manner, the cap portion can more easily engage with the outer peripheral surface of the base portion. At this time, the cap portion engages while expanding/contracting in response to the tapering (taper) shape of the outer peripheral surface. Thus, the interior of the package on which the semiconductor light-emitting element is placed can be more reliably airtightly sealed.

A method for manufacturing a semiconductor light-emitting device according to a second aspect of the present invention includes the steps of forming a base portion and a cap portion, mounting a semiconductor light-emitting element on the base portion, and sealing the semiconductor light-emitting element by engaging the base portion with the cap portion, while the step of forming the base portion and the cap portion includes a step of forming at least either one of the base portion and the cap portion by molding a mixture of resin and a gas absorbent.

In the method for manufacturing a semiconductor light-emitting device according to the second aspect of the present invention, as hereinabove described, at least one of the base portion and the cap portion is formed by molding the mixture of the resin and the gas absorbent, whereby volatile organic gas generated from the resin can be absorbed by the gas absorbent mixed into the resin also in the case of employing the resin as the material constituting at least either one of the base portion and the cap portion. Thus, gas can be inhibited from filling up a package sealing the semiconductor light-emitting element, whereby the same can be inhibited from being excited or decomposed by light emitted from the semiconductor light-emitting element and being formed as a solid incrustation on a light-emitting facet of the semiconductor light-emitting element. Consequently, a semiconductor light-emitting device capable of inhibiting the semiconductor light-emitting element from deterioration can be obtained.

Further, the gas absorbent is mixed into at least either one of the base portion and the cap portion, whereby no member containing the gas absorbent may be separately set in the package. Thus, the internal volume of the package may not be enlarged, whereby the size of the package can be inhibited from enlargement.

Preferably in the aforementioned method for manufacturing a semiconductor light-emitting device according to the second aspect, the base portion and the cap portion are both made of mixtures of the resin and the gas absorbent, and the ratio of the gas absorbent mixed into the resin constituting the cap portion with respect to the resin is smaller than the ratio of the gas absorbent mixed into the resin constituting the base portion with respect to the resin. When forming the method for manufacturing a semiconductor light-emitting device in this manner, the cap portion in which elasticity resulting from the resin is easily maintained can be formed, whereby the package can be sealed by reliably engaging the base portion with the cap portion.

An optical device according to a third aspect of the present invention includes a semiconductor light-emitting device including a semiconductor light-emitting element and a package sealing the semiconductor light-emitting element and an optical system controlling light emitted from the semiconductor light-emitting device, while the package has a base portion mounted with the semiconductor light-emitting element and a cap portion mounted on the base portion for covering the semiconductor light-emitting element, and at least one of the base portion and the cap portion is made of a mixture of resin and a gas absorbent.

In the optical device according to the third aspect of the present invention, as hereinabove described, at least either one of the base portion and the cap portion is made of the mixture of the resin and the gas absorbent, whereby volatile organic gas generated from the resin can be absorbed by the gas absorbent mixed into the resin also in the case of employing the resin as the material constituting at least either one of the base portion and the cap portion. Thus, the organic gas can be inhibited from filling up the package sealing the semiconductor light-emitting element, whereby the same can be inhibited from being excited or decomposed by light emitted from the semiconductor light-emitting element and being formed as a solid incrustation on a light-emitting facet of the semiconductor light-emitting element. Consequently, the semiconductor light-emitting element can be inhibited from deterioration.

Further, the gas absorbent is mixed into at least one of the base portion and the cap portion, whereby no member containing the gas absorbent may be separately set in the package. Thus, the internal volume of the package may not be enlarged, whereby the size of the package can be inhibited from enlargement.

### BRIEF DESCRIPTION OF THE DRAWINGS

FIG. 1 An exploded perspective view showing a state where a cap portion and a base portion of a semiconductor laser device according to a first embodiment of the present invention are separated from each other.

FIG. 2 A longitudinal sectional view along a centerline in the width direction of the semiconductor laser device according to the first embodiment of the present invention.

FIG. 3 An enlarged sectional view of a mixture of resin and a gas absorbent according to the present invention.

FIG. 4 A top plan view of the semiconductor laser device according to the first embodiment of the present invention.

FIG. 5 A front elevational view at a time of observing the semiconductor laser device according to the first embodiment of the present invention from a laser beam emitting direction in a state removing the cap portion.

FIG. 6 A top plan view for illustrating a manufacturing process for the semiconductor laser device according to the first embodiment of the present invention.

FIG. 7 A top plan view for illustrating the manufacturing process for the semiconductor laser device according to the first embodiment of the present invention.

FIG. 8 A longitudinal sectional view along a centerline in the width direction of a semiconductor laser device according to a first modification of the first embodiment of the present invention.

FIG. 9 A top plan view of a semiconductor laser device according to a second modification of the first embodiment of the present invention.

FIG. 10 A perspective view showing a state removing a cap portion of a semiconductor laser device according to a third modification of the first embodiment of the present invention.

FIG. 11 A perspective view showing a state removing a cap portion of a semiconductor laser device according to a second embodiment of the present invention.

FIG. 12 A perspective view showing a state removing a cap portion of a semiconductor laser device according to a modification of the second embodiment of the present invention.

FIG. 13 A perspective view showing a state removing a cap portion of a semiconductor laser device according to a third embodiment of the present invention.

FIG. 14 A top plan view for illustrating a manufacturing process for the semiconductor laser device according to the third embodiment of the present invention.

FIG. 15 A perspective view showing a state removing a cap portion of a semiconductor laser device according to a fourth embodiment of the present invention.

FIG. 16 A sectional view at a time of observing the semiconductor laser device according to the fourth embodiment of the present invention from a laser beam emitting direction in the state removing the cap portion.

FIG. 17 A top plan view for illustrating a manufacturing process for the semiconductor laser device according to the fourth embodiment of the present invention.

FIG. 18 A perspective view showing a state removing a cap portion of a semiconductor laser device according to a fifth embodiment of the present invention.

FIG. 19 A top plan view showing the state removing the cap portion of the semiconductor laser device according to the fifth embodiment of the present invention.

FIG. 20 A top plan view showing a state removing a cap portion of a semiconductor laser device according to a modification of the fifth embodiment of the present invention.

FIG. 21 An exploded perspective view showing a state where a cap portion and a base portion of a semiconductor laser device according to a sixth embodiment of the present invention are separated from each other.

FIG. 22 A front sectional view at a time of observing a three-wavelength semiconductor laser device according to a seventh embodiment of the present invention from a laser beam emitting direction in a state removing a cap portion.

FIG. 23 A top plan view showing the state removing the cap portion of the three-wavelength semiconductor laser device according to the seventh embodiment of the present invention.

FIG. 24 An exploded perspective view showing a state where a cap portion and a base portion of a three-wavelength semiconductor laser device according to a modification of the seventh embodiment of the present invention are separated from each other.

FIG. 25 A schematic diagram showing the structure of an optical pickup device including a three-wavelength semiconductor laser device according to an eighth embodiment of the present invention.

FIG. 26 A block diagram of an optical disk device including an optical pickup device mounted with a three-wavelength semiconductor laser device according to a ninth embodiment of the present invention.

FIG. 27 A front elevational view at a time of observing an RGB three-wavelength semiconductor laser device according to a tenth embodiment of the present invention from a laser beam emitting direction in a state removing a cap portion.

FIG. 28 A block diagram of a projector device including the RGB three-wavelength semiconductor laser device according to the tenth embodiment of the present invention.

FIG. 29 A block diagram of a projector device including an RGB three-wavelength semiconductor laser device according to an eleventh embodiment of the present invention.

FIG. 30 A timing chart showing a state where a control portion transmits signals in a time-series manner in the projector device including the RGB three-wavelength semiconductor laser device according to the eleventh embodiment of the present invention.

FIG. 31 A longitudinal sectional view along a centerline in the width direction of a base portion constituting a semiconductor laser device according to a fourth modification of the first embodiment of the present invention.

FIG. 32 A longitudinal sectional view along a centerline in the width direction of a base portion constituting a semiconductor laser device according to a fifth modification of the first embodiment of the present invention.

FIG. 33 A top plan view showing a state removing a cap portion of a semiconductor laser device according to a sixth modification of the first embodiment of the present invention.

### MODES FOR CARRYING OUT THE INVENTION

Embodiments of the present invention are now described on the basis of the drawings.

### First Embodiment

First, the structure of a semiconductor laser device 100 according to a first embodiment of the present invention is described with reference to FIGS. 1 to 5. The semiconductor laser device 100 is an example of the “semiconductor light-emitting device” in the present invention.

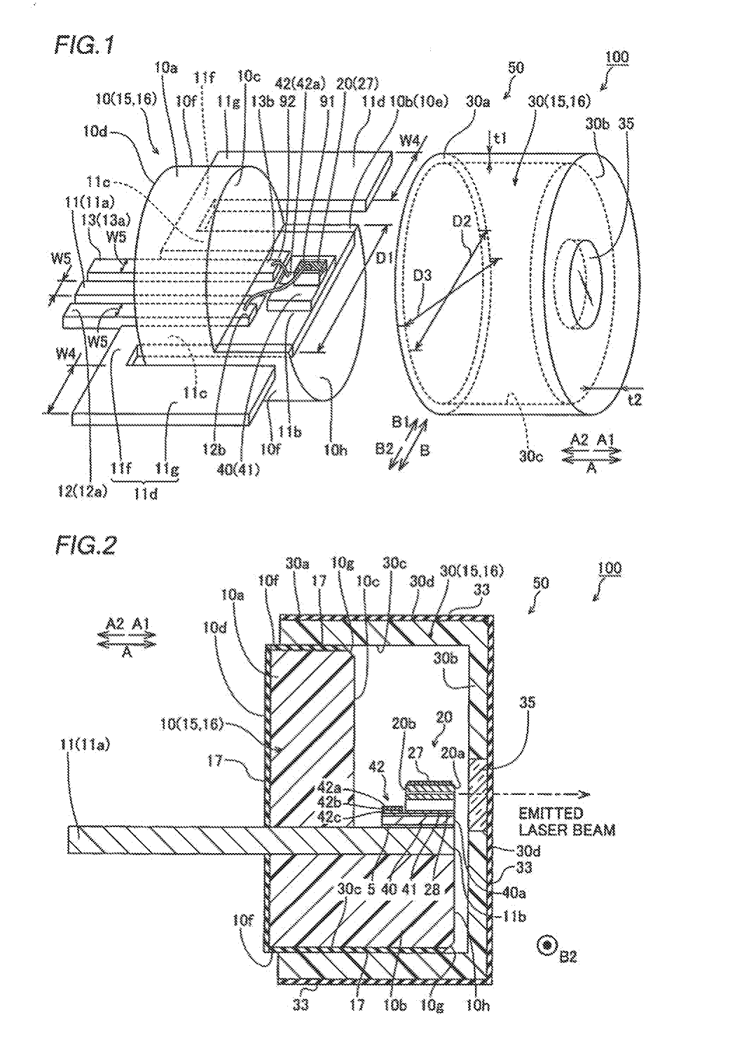

The semiconductor laser device 100 includes a blue-violet semiconductor laser element 20 having a lasing wavelength of about 405 nm and a package 50 sealing the blue-violet semiconductor laser element 20, as shown in FIGS. 1 and 2. The package 50 has a base portion 10 mounted with the blue-violet semiconductor laser element 20 and a cap portion 30 mounted on the base portion 10 for covering the blue-violet semiconductor laser element 20. The blue-violet semiconductor laser element 20 is an example of the “semiconductor light-emitting element” in the present invention.

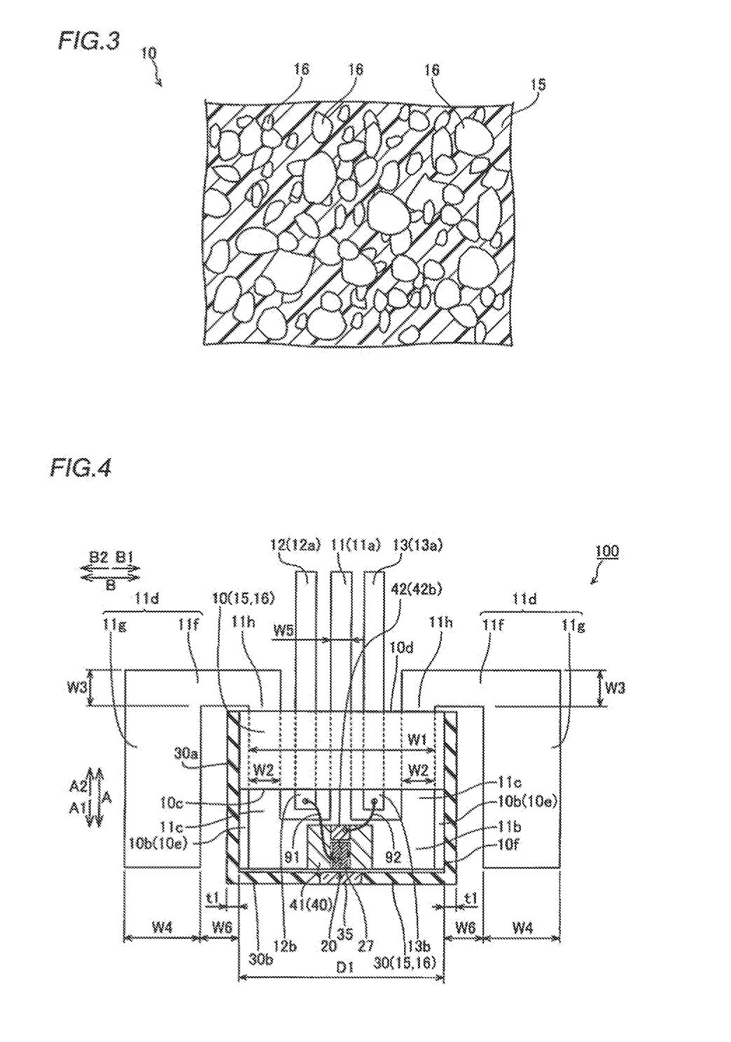

As shown in FIGS. 1 and 5, the base portion 10 has a substantially columnar header portion 10a having an outer diameter D1 and a protruding block portion 10b in which about half (whole surface 10h) of the lower side of a front surface 10c of the header portion 10a extends frontward (in a laser beam emitting direction (direction A1)). As shown in FIG. 3, the base portion 10 is made of a mixture of a particulate gas absorbent 16 (synthetic zeolite) mixed at a prescribed ratio into epoxy resin 15. The gas absorbent 16 is present in a state where individual particles have particle diameters of at least several 10 μm and not more than several 100 μm. This particulate gas absorbent 16 has a role of absorbing volatile organic gas generated by the resin 15. The epoxy resin and the synthetic zeolite are examples of the “resin” and the “gas absorbent” in the present invention respectively.

Lead terminals 11, 12 and 13 consisting of a lead frame of a metal having a width W5 are arranged to pass through the base portion 10 from the front surface 10c side (A1 side) to a rear surface 10d side (A2 side) in a state insulated from each other. The lead terminal 11 passes through a substantial center of the header portion 10a (front surface 10c) of the base portion 10. The lead terminals 12 and 13 are arranged on the same plane on respective outer sides (on a B2 side and a B1 side) in the width direction (direction B) of the lead terminal 11. The lead terminals 11, 12 and 13 have rear end regions 11a, 12a and 13a extending rearward (on the A2 side) respectively. The rear end regions 11a, 12a and 13a are exposed from the rear surface 10d of the base portion 10. The lead terminal 11 is an example of the “first lead terminal” in the present invention.

As shown in FIGS. 4 and 5, the lead terminals 11, 12 and 13 have front-side (A1-side) front end regions 11b, 12b and 13b respectively. The front end regions 11b, 12b and 13b are exposed from the front surface 10c of the header portion 10a, and arranged on an upper surface 10e of the protruding block portion 10b. The front end region 11b of the lead terminal 11 spreads in the direction B on a front side of the front end regions 12b and 13b of the lead terminals 12 and 13 on the protruding block portion 10b, and has a width W1 (W1<D1). The blue-violet semiconductor laser element 20 is fixed to a substantial center of the front end region 11b. The front end region 11b is an example of the “element placement portion” in the present invention.

As shown in FIG. 4, a pair of heat radiation portions 11d substantially symmetrically arranged on both sides (opposite sides (outer sides) of the lead terminals 12 and 13 to the lead terminal 11) in the direction B with respect to the lead terminal 11 as a center are connected to the front end region 11b of the lead terminal 11. When detailedly described, connection portions 11c extending rearward (in a direction A2) from both end portions in the width direction (on the B2 side and the B1 side) of the front end region 11b of the lead terminal 11 are formed. These connection portions 11c have a width W2. Further, the connection portions 11c rearwardly extend from the front end region 11b on sides (on the B2 side and the B1 side) outward beyond the lead terminals 12 and 13, and pass through the base portion 10 from the front surface 10c to the rear surface 10d of the base portion 10. The heat radiation portions 11d are connected to rear end regions 11h of the connection portions 11c exposed from the rear surface 10d of the base portion 10. The rear end regions 11h of the connection portions 11c are examples of the “connection region” in the present invention. The heat radiation portions 11d include first heat radiation portions 11f, having a width W3, whose first ends are connected to the rear end regions 11h of the connection portions 11c and second heat radiation portions 11g, having a width W4, connected to second ends of the first heat radiation portions 11f. At this time, after the first heat radiation portions 11f extend by a distance W6 on an outer side (in a direction B2 or a direction B1) of an outer peripheral surface 10f of the base portion 10, the second heat radiation portions 11g extend while changing the direction frontward (in the direction A1) from the second ends of the first heat radiation portions 11f. Therefore, the second heat radiation portions 11g extend substantially parallelly to the outer peripheral surface 10f at an interval of the distance W6 with respect to the outer peripheral surface 10f of the base portion 10, as shown in FIG. 4. In other words, the connection portions 11c and the heat radiation portions 11d have substantially U shapes in plan view, and are formed on the same plane as the upper surface 10e of the protruding block portion 10b.

Both of the width W2 of the connection portions 11c and the width W4 of the second heat radiation portions 11g are wider (W2>W5 and W4>W5) than the width W5 of a portion of the lead terminal 11 passing through the base portion 10. Therefore, heat generated by the blue-violet semiconductor laser element 20 operating in the package 50 is radiated to the exterior of the semiconductor laser device 100 through the submount 40, the front end region 11b and the heat radiation portions 11d on both sides.

The cap portion 30 is made of a mixture of a gas absorbent consisting of synthetic zeolite and silicone resin (silicone resin) having translucency and elasticity, and constituted of a substantially cylindrically formed sidewall portion 30a having an inner diameter D2 and an outer diameter D3 and a bottom surface portion 30b blocking a first side (A1 side) of the sidewall portion 30a, as shown in FIG. 1. The silicone resin is an example of the “resin” in the present invention. The sidewall portion 30a has a thickness (radial thickness) of about 0.5 mm. The bottom surface portion 30b has a thickness t2 (t2≧t1) slightly larger than the thickness t1. A light transmission portion 35 through which a laser beam emitted from the blue-violet semiconductor laser element 20 is transmittable toward the exterior is formed on a central portion of the bottom surface portion 30b having a substantially circular shape. While the light transmission portion 35 contains no gas absorbent and hence has translucency, the sidewall portion 30a and the bottom surface portion 30b contain the gas absorbent and hence have no translucency.

As shown in FIG. 3, each of the base portion 10 and the cap portion 30 is made of the mixture in which the particulate gas absorbent (synthetic zeolite) 16 is mixed at the prescribed ratio with respect to the resin (epoxy resin or silicone resin) 15. In the gas absorbent 16, the individual particles are present in the state having the particle diameters of at least several 10 μm and not more than several 100 μm. This particulate gas absorbent 16 has the role of absorbing the volatile organic gas generated from the resin 15. In the base portion 10, the gas absorbent 16 is preferably mixed in the range of at least about 70 weight % and not more than about 90 weight % with respect to the resin (epoxy resin) 15. Thus, the ratio of the epoxy resin occupying the base portion 10 so lowers that the quantity of generation of the organic gas generated from the epoxy resin is suppressed, while it becomes possible at the same time to reliably absorb the organic gas by the gas absorbent 16 whose ratio occupying the base portion 10 is relatively increased. In the cap portion 30, the gas absorbent 16 is preferably mixed in the range of at least about 40 weight % and not more than about 70 weight % with respect to the resin (silicone resin) 15. Thus, the quantity of generation of the organic gas generated from the silicone resin is suppressed while it becomes possible at the same time to reliably absorb the organic gas, similarly to the base portion 10. The ratio of the gas absorbent 16 mixed into the cap portion 30 is smaller than the gas absorbent 16 mixed into the base portion 10, whereby elasticity of the silicone resin in the cap portion 30 can be maintained. The sidewall portion 30a and the bottom surface portion 30b of the cap portion 30 have no translucency since the gas absorbent is mixed thereinto, while the light transmission portion 35 has translucency since no gas absorbent is mixed thereinto.

As shown in FIG. 2, a pad electrode 41 for die-bonding the blue-violet semiconductor laser device 20 and a monitoring PD (photodiode) 42 is formed on the upper surface of the submount 40. The blue-violet semiconductor laser device 20 is bonded to a prescribed region of the front-side (A1-side) upper surface of the pad electrode 41. The monitoring PD 42 is bonded to a prescribed region on the rear-side (A2-side) upper surface of the pad electrode 41. The submount 40 is bonded to the surface of the front end region 11b of the lead terminal 11 through a conductive adhesive layer 5 whose lower surface is made of Au—Sn solder.

As shown in FIG. 2, the monitoring PD 42 has a p-type region 42b and an n-type region 42c, and the side of the n-type region 42c is bonded to the submount 40. Thus, a laser beam emitted from a light-reflecting surface 20b of the blue-violet semiconductor laser element 20 is incident upon the upper surface (photoreceiving surface 42a) of the p-type region 42b of the monitoring PD 42. A light-emitting surface 20a of the blue-violet semiconductor laser element 20 aligns with a facet 40a of the submount 40 on the A1 side, a front end region 11b of the lead terminal 11 and a front surface 10h of the protruding block portion 10b of the base portion 10 on the same plane.

The light-emitting surface 20a and the light-reflecting surface 20b are distinguished from each other by large-small relation between light intensity levels of laser beams emitted from the respective facets with respect to a pair of cavity facets formed on the blue-violet semiconductor laser element 20. In other words, the facet where the light intensity of the emitted laser beam is relatively large is the light-emitting surface 20a, and the facet where the same is relatively small is the light-reflecting surface 20b.

As shown in FIG. 1, the blue-violet semiconductor laser element 20 has a cavity length (direction A) of at least about 250 μm and not more than about 400 μm, and has an element width (direction B) of at least about 100 μm and not more than about 200 μm. Further, the blue-violet semiconductor laser element 20 has a thickness (maximum thickness) of about 100 μm.

In the blue-violet semiconductor laser element 20, an n-type cladding layer 22 made of Si-doped n-type AlGaN, an active layer 23 having such an MQW structure that quantum well layers made of InGaN having a high In composition and barrier layers made of GaN are alternately stacked and a p-type cladding layer 24 made of Mg-doped p-type AlGaN are formed in this order on the upper surface of an n-type GaN substrate 21, as shown in FIG. 5.

On the p-type cladding layer 24, a ridge (projecting portion) 25, having a width of about 1.5 μm, extending along a direction (direction A in FIG. 1) perpendicular to the plane of FIG. 5 is so formed that a waveguide structure is formed. Further, a current blocking layer 26 made of SiO₂ covering the upper surface of the p-type cladding layer 24 other than the ridge 25 and both side surfaces of the ridge 25 is formed. A p-side electrode 27 made of Au or the like is formed on the upper surfaces of the ridge 25 of the p-type cladding layer 24 and the current blocking layer 26.

An n-side electrode 28 in which an Al layer, a Pt layer and an Au layer are stacked in this order successively from the side close to the n-type GaN substrate 21 is formed substantially on the overall region of the lower surface of the n-type GaN substrate 21. Dielectric multilayer films of low reflectance and high reflectance are formed on the light-emitting surface 20a and the light-reflecting surface 20b (see FIG. 2) of the blue-violet semiconductor laser element 20 respectively.

The n-side electrode 28 of the blue-violet semiconductor laser element 20 and the pad electrode 41 are bonded to each other through a conductive adhesive layer (not shown), whereby the blue-violet semiconductor laser element 20 is bonded onto the submount 40 by a junction-up system (see FIG. 5).

As shown in FIG. 1, the blue-violet semiconductor laser element 20 is connected to a front facet 12b of the lead terminal 12 through a metal wire 91, made of Au or the like, wire-bonded to the p-side electrode 27. The monitoring PD 42 is connected to a front facet 13b of the lead terminal 13 through a metal wire 92, made of Au or the like, wire-bonded to the p-type region 42b. The n-side electrode 28 of the blue-violet semiconductor laser element 20 and the n-type region 42c of the monitoring PD 42 are both electrically connected to the lead terminal 11 through the submount 40.

As shown in FIG. 2, the sidewall portion 30a of the cap portion 30 is slid from the A1 side toward the A2 side and engaged with the header portion 10a, whereby the blue-violet semiconductor laser element 20 placed on the protruding block portion 10b is airtightly sealed in the package 50. In a state not engaging the cap portion 30 with the header portion 10a, the inner diameter D2 (see FIG. 1) of the cap portion 30 is preferably smaller by about 1% than the outer diameter D1 (see FIG. 1) of the header portion 10a. Thus, it becomes possible to engage an inner side surface 30c of the sidewall portion 30a of the cap portion 30 with the outer peripheral surface 10f of the base portion 10 in a state substantially completely brought into close contact therewith. Chamfering is circumferentially performed on an edge portion 10g where the outer peripheral surface 10f and the front surface 10c of the base portion 10 intersect with each other. Thus, the inner side surface 30c of the cap portion 30 smoothly engages with the outer peripheral surface 10f of the base portion 10 when the cap portion 30 is engaged with the header portion 10a.

The sidewall portion 30a of the cap portion 30 is engaged to be inserted between the base portion 10 and the heat radiation portions 11d, whereby the heat radiation portions 11d of the lead terminal 11 are arranged on the outer sides of the cap portion 30 (sidewall portion 30a) in the state (see FIG. 2) where the cap portion 30 engages with the header portion 10a.

As shown in FIG. 2, a gas barrier layer 17 made of SiO₂ is continuously formed on the outer peripheral surface 10f of the base portion 10 and the rear surface 10d of the header portion 10a. Further, a gas barrier layer 33 made of SiO₂ is continuously formed on the sidewall portion 30a of the cap portion 30 and an outer surface 30d of the bottom surface portion 30b. In other words, epoxy resin or silicone resin has high gas permeability due to an amorphous structure, and hence there is an apprehension that low-molecular siloxane or volatile organic gas present in the exterior (in the atmosphere) of the semiconductor laser device 100 permeates the epoxy resin or the silicone resin and penetrates into the package 50 in a case where the gas barrier layers 17 and 33 are not provided, even if the package 50 is sealed by engaging the cap portion 30 with the header portion 10a. On the other hand, external penetration of organic gas can be prevented by providing the gas barrier layers 17 and 33. The gas barrier layers 17 and 33 may simply have thicknesses of several 10 nm. The base portion 10 and the cap portion 30 contain the gas absorbent in the resin and the internal structures thereof is porous states, and hence it is extremely effective to provide the gas barrier layers 17 and 33 in order to block external penetration of the organic gas or the like. The gas barrier layer 33 formed on the outer surface 30d of the cap portion 30 is formed also on the outer surface of the light transmission portion 35.

A manufacturing process for the semiconductor laser device 100 is now described with reference to FIGS. 1 to 7.

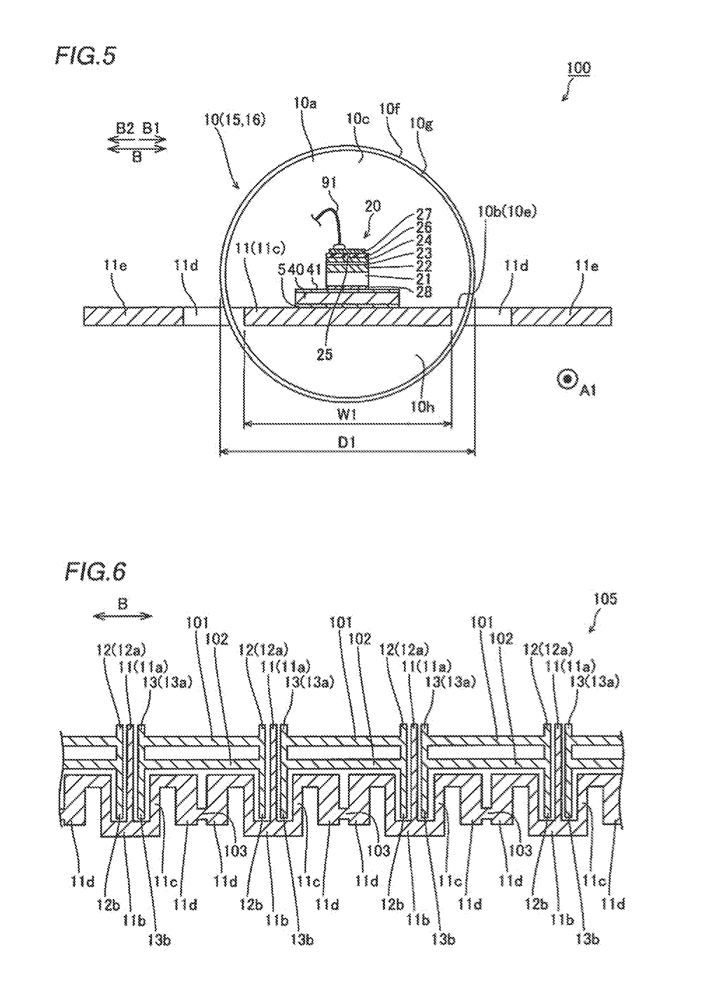

First, a lead frame 105 in which such lead terminals 11 that heat radiation portions 11d and connection portions 11c are formed integrally with front end regions 11b, and lead terminals 12 and 13 arranged on both sides of the lead terminals 11 are repeatedly patterned in the lateral direction (direction B) is formed by etching a metal plate consisting of a belt-shaped thin plate of iron or copper, as shown in FIG. 6. At this time, all lead terminals 12 and 13 are so patterned that they are coupled with coupling portions 101 and 102 extending in the lateral direction (direction B). Further, all heat radiation portions 11d are so patterned that they are coupled with coupling portions 103 extending in the lateral direction.

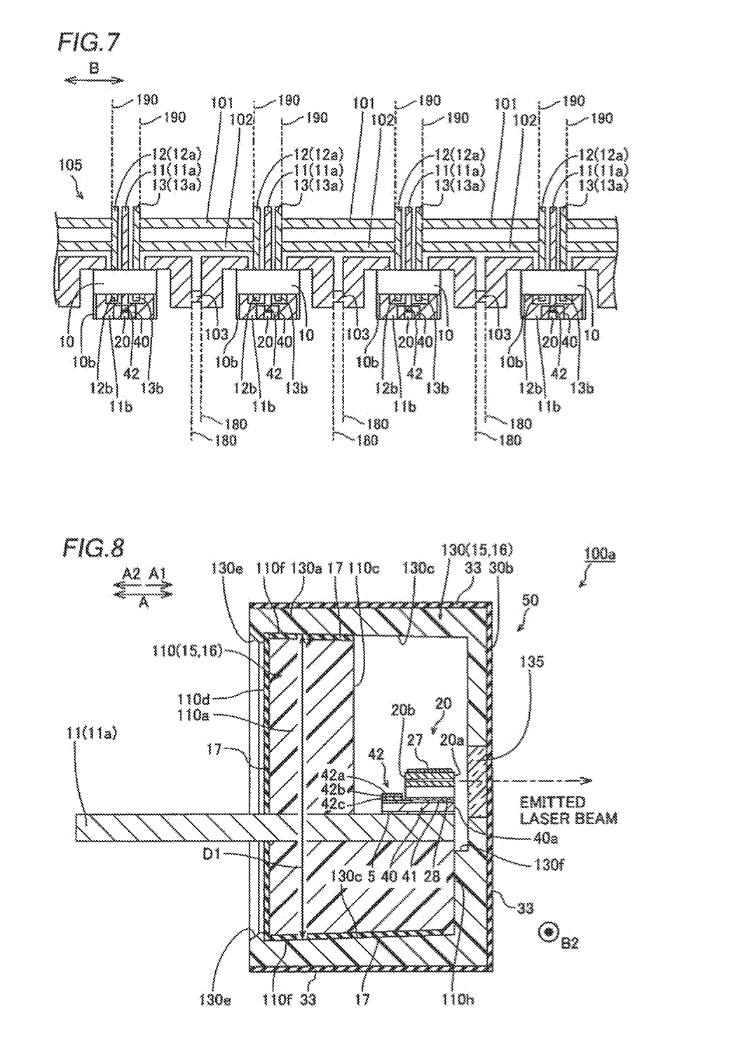

Thereafter base portions 10 each fixing a set of lead terminals 11 to 13 are molded by a mixture of epoxy resin and gas absorbent, as shown in FIGS. 1 and 7. At this time, the all lead terminals 11 to 13 pass through the base portions 10, and are so fixed that all front end regions 11b to 13b and rear end regions 11a to 13a are exposed from the base portions 10. The base portions 10 are formed on the sides of the front end regions 11b to 13b of the lead terminals 11 to 13, and also include connection portions 11c therein. Such protruding block portions 10b that about half of lower sides of front surfaces 10c of the base portions 10 extend frontward are also formed under (C1 side in FIG. 2) the front end regions 11b to 13b of the lead terminals 11 to 13.

Thereafter the gas barrier layer 17 (see FIG. 2) made of SiO₂ is formed on header portions 10a of the base portions 10 and outer peripheral surfaces 10f of the protruding block portions 10b and on rear surfaces 10d of the header portions 10a by vacuum evaporation.

On the other hand, a mixture of unhardened silicone resin prepared by mixing silicone resin and a hardening agent in the ratio of about 10 to 1 and gas absorbent is poured into a mold (not shown) having a prescribed shape, and hardened by heating the same under a temperature condition of about 150° C. for about 30 minutes. Thus, sidewall portions 30a of cap portions 30 and such bottom surfaces portions 30b (see FIG. 2) that openings are formed in substantially central portions are molded. Before mixing synthetic zeolite into the silicone resin at this time, heat treatment is more preferably performed on the synthetic zeolite. Thus, absorbability of the synthetic zeolite can be improved.

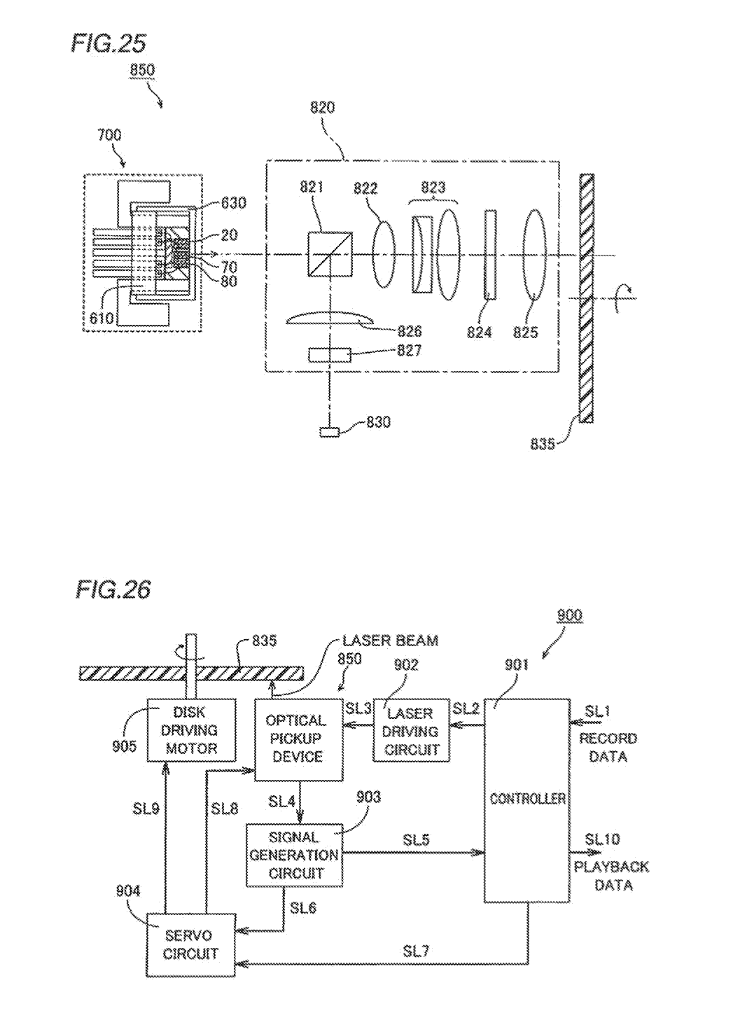

Thereafter unhardened silicone resin into which no gas absorbent is mixed and the cap portions 30 (portions of the sidewall portions 30a and the bottom surface portions 30b) molded in the aforementioned step are introduced into the mold (not shown) having a prescribed shape, and heated again under a temperature condition of about 150° C. for about 30 minutes. Thus, light transmission portions 35 (see FIG. 25) having translucency are molded in the openings having been formed in the substantially central portions of the bottom surface portions 30b.

Thereafter the cap portions 30 are taken out of the mold and heated in an oven brought into a reduced-pressure state by an oil-free pump under a temperature condition of about 240° C. for about two days, thereby removing low-molecular siloxane contained in the silicone resin. Even if heating the cap portions 30 for about two days, the low-molecular siloxane in the silicone resin cannot be completely removed. However, the residual low-molecular siloxane is reduced to a quantity absorbable by the gas absorbent mixed into the cap portions 30.

Thereafter the gas barrier layer 33 (see FIG. 2) made of SiO₂ is formed on the sidewall portions 30a of the cap portions 30 and the outer surfaces 30d of the bottom surface portions 30b by vacuum evaporation. Thus, the cap portions 30 are formed.

Further, chips of blue-violet semiconductor laser elements 20 and monitoring PDs 42 are prepared by a prescribed manufacturing process. Then, the chips of the blue-violet semiconductor laser elements 20 and the monitoring PDs 42 are bonded to such submounts 40 that pad electrodes 41 are formed on single surfaces. At this time, sides of n-side electrodes 28 of the blue-violet semiconductor laser elements 20 and sides of n-type regions 42c of the monitoring PDs 42 are bonded to the pad electrodes 41.

Thereafter the submounts 40 are bonded to substantial centers (lateral direction) of the upper surfaces of the front end regions 11b (see FIG. 4) of the lead terminals 11 through conductive adhesive layers 5 (see FIG. 5), as shown in FIG. 7. At this time, lower surface sides of the submounts 40 to which the blue-violet semiconductor laser elements 20 and the monitoring PDs 42 are not bonded are bonded to the upper surfaces of the front end regions 11b. Further, the submounts 40 are so bonded that light-reflecting surfaces 20b of the blue-violet semiconductor laser elements 20 are opposed to the front surfaces 10c of the base portions 10.

Thereafter p-side electrodes 27 of the blue-violet semiconductor laser elements 20 are connected with front end regions 12b of lead terminals 12 by metal wires 91, as shown in FIG. 1. Further, p-type regions 42b of the monitoring PDs 42 are connected with front end regions 13b of lead terminals 13 by metal wires 92. FIG. 7 omits illustration of the metal wires 91 and 92.

Thereafter coupling portions 101, 102 and 103 are removed by cutting the lead frame 105 along separation lines 180 and 190, as shown in FIG. 7. Finally, the cap portion 30 is engagingly put on the individual separated head portion 10a of the base portion 10. Thus, the semiconductor laser device 100 (see FIG. 2) is formed.

The base portion 10 and the cap portion 30 are made of the mixtures of the epoxy resin and the silicone resin and the gas absorbent, whereby volatile organic gas generated from the resin of the base portion 10 and the cap portion 30 can be absorbed by the gas absorbents. Thus, the organic gas can be inhibited from filling up the package 50 sealing the blue-violet semiconductor laser element 20, whereby the organic gas concentration in the package 50 can be reduced. Consequently, the organic gas can be inhibited from being excited or decomposed by the laser beam emitted from the blue-violet semiconductor laser element 20 and being formed as a solid incrustation on the light-emitting surface 20a, whereby the blue-violet semiconductor laser element 20 can be inhibited from deterioration.

Further, each of the base portion 10 and the cap portion 30 is made of the resin 15 into which the gas absorbent 16 is mixed, whereby no member containing a gas absorbent may be separately set in the package 50. Thus, the internal volume of the package 50 may not be enlarged, whereby the size of the semiconductor laser device 100 can be inhibited from enlargement.

The size of the package 50 is substantially equalized with a package size in a case of forming the base portion 10 and the cap portion 30 without containing the gas absorbent 16, whereby the volume of the resin 15 occupying the package 50 can be reduced due to the contained gas absorbent 16. Thus, generation of organic gas can be suppressed, whereby the blue-violet semiconductor laser element 20 can be inhibited from deterioration.

The silicone resin having translucency is used for the cap portion 30 including the light transmission portion 35, whereby the cap portion 30 can be easily manufactured, while the structure of the cap portion 30 can be simplified.

In order to confirm usefulness of the employment of the silicone resin for the light transmission portion 35, the following experiment was conducted: First, a light transmission portion 35 was prepared from silicone resin (by Shin-Etsu Chemical Co., Ltd.: KE-106) consisting of platelike polydimethylsiloxane having a thickness of about 1 mm, and this was arranged at a distance of 1 mm from a light-emitting surface 20a. Then, a laser beam adjusted to an output of 10 mW by Auto Power Control (APC) was applied from a blue-violet semiconductor laser element 20 to the light transmission portion 35 for 1000 hours under a condition of 70° C. Consequently, it was confirmed that the transmittance of the light transmission portion 35 remained unchanged. In a case of applying a laser beam to a light transmission portion prepared from PMMA (transparent acrylic resin) having a thickness of 1 mm under the same conditions as comparative example, a region to which the laser beam was applied opacified due to deterioration. From this result, the usefulness of the employment of the silicone resin for the cap portion 30 was confirmed.

The resin 15 has translucency, and the cap portion 30 having the light transmission portion 35 can be formed by using the same resin 15 having translucency by mixing the gas absorbent 16 into the mixture constituting the cap portion 30 other than the light transmission portion 35, whereby the cap portion 30 can be easily manufactured, while the structure of the cap portion 30 can be simplified. Further, the gas absorbent 16 is mixed into the resin 15 constituting the cap portion 30 other than the light transmission portion 35, whereby neither light absorption nor light scattering by the gas absorbent 16 takes place in the light transmission portion 35. Thus, outgoing light can be reliably emitted from the light transmission portion 35, while organic gas generated from the resin 15 of the cap portion 30 including the light transmission portion 35 can be inhibited from filling up the package 50.

In addition, the synthetic zeolite is employed for the gas absorbent 16, whereby organic gas generated from the resin 15 can be sufficiently absorbed, and the base portion 10 and the cap portion 30 can both be easily formed by the mixture of the resin 15 and the gas absorbent 16.

The gas barrier layer 17 is formed on the outer peripheral surface 10f of the base portion 10 made of the mixture and on the rear surface 10d of the header portion 10a while the gas barrier layer 33 is formed on the sidewall portion 30a of the cap portion 30 and the outer surface 30d of the bottom surface portion 30a so that low-molecular siloxane, volatile organic gas etc. present in the exterior (in the atmosphere) of the semiconductor laser device 100 can be inhibited from permeating the material of the base portion 10 or the cap portion 30 and penetrating into the package 50, whereby deterioration of the blue-violet semiconductor laser element 20 can be further suppressed.

The semiconductor laser device 100 so includes the heat radiation portions 11d extending on regions outside the outer peripheral surface 10f of the base portion 10 that heat radiation areas can be sufficiently ensured, whereby heat generated by the blue-violet semiconductor laser element 20 can be sufficiently radiated through the heat radiation portions 11d. Further, the heat radiation portions 11d and the connection portions 11c are connected with each other on the rear surface 10d of the base portion 10, whereby the cap portion 30 for sealing the blue-violet semiconductor laser element 20 can be mounted on the front surface 10c side of the base portion 10 without interfering with the heat radiation portions 11d.

The rear end regions 11h of the connection portions 11c are so exposed from the rear surface 10d of the base portion 10 that the heat radiation portions 11d can be easily exposed to the exterior of the base portion 10, whereby heat radiation characteristics in the heat radiation portions 11d can be improved.

The heat radiation portions 11d are arranged on the outer sides of the plurality of lead terminals 11 to 13 arranged on the same plane as the base portion 10. In other words, in a direction parallel to the same plane of the base portion 10, the lead terminal 12 or 13 positioned on the outermost side among the lead terminals 11 to 13 is held and arranged between either heat radiation portion 11d and the other lead terminal 11 while the heat radiation portions 11d are not arranged between the lead terminals 11 to 13. The heat radiation portions 11d are so formed in this manner that the heat radiation portions 11d radiating heat from the blue-violet semiconductor laser element 20 may not be arranged in a limited space between the lead terminal 11 and the lead terminal 12 (13), whereby the surface areas of the heat radiation portions 11d can be enlarged. Thus, the heat radiation characteristics in the heat radiation portions 11d can be improved. Further, the lead terminals 11 to 13 and the heat radiation portions 11d are arranged in the same plane, whereby each lead terminal and the heat radiation portions 11d can be easily formed by a lead frame or the like, for example. Further, also at a time of mounting this semiconductor laser device 100 on a housing of an optical pickup device or the like, for example, the heat radiation portions 11d and the housing can be easily fixed to each other, whereby the heat generated by the blue-violet semiconductor laser element 20 can be easily radiated to the housing.

The front end region 11b is formed integrally with the lead terminal 11, whereby the lead terminal 11 can be made to also play the role of a heat radiation function. Thus, heat radiation properties of the semiconductor laser device 100 can be further improved. The width W2 of the connection portions 11c and the width W4 of the second heat radiation portions 11g are both formed to be wider (W2>W5 and W4>W5) than the width W5 of the portion of the lead terminal 11 passing through the base portion 10. Thus, the heat generated by the blue-violet semiconductor laser element 20 is more easily transmitted (thermally conducted) toward the connection portions 11c and the heat radiation portions 11d than toward the lead terminal 11, after being transmitted to the front end region 11b of the lead terminal 11 through the submount 40. Thus, the heat of the blue-violet semiconductor laser element 20 is transmitted to the heat radiation portions 11d linked with the respective connection portions 11c and can be reliably radiated to the exterior of the semiconductor laser device 100.

The resin 15 has elasticity while the base portion 10 and the cap portion 30 engage with each other thereby sealing the blue-violet semiconductor laser element 20 so that the inner side surface 30c of the cap portion 30 can be easily brought into close contact with the outer peripheral surface 10f of the base portion 10, whereby the interior of the package 50 can be easily sealed. In other words, no adhesive or the like for sealing may be further used, whereby generation of organic gas can be suppressed.

The ratio of the gas absorbent 16 mixed into the resin (silicone resin) 15 constituting the cap portion 30 to the silicone resin is smaller than the ratio of the gas absorbent 16 mixed into the resin (epoxy resin) constituting the base portion 10 to the epoxy resin. Thus, elasticity resulting from the silicone resin in the cap portion 30 can be easily maintained, whereby the base portion 10 and the cap portion 30 can be reliably engaged with each other.

(First Modification of First Embodiment)

A first modification of the first embodiment is described with reference to FIG. 6. In a semiconductor laser device 100a according to this first modification of the first embodiment, an outer peripheral surface 110f of a base portion 110 on a portion engaging with a cap portion 130 has a taper shape tapering frontward from a rear portion, dissimilarly to the first embodiment. The figure illustrates structures similar to those in the first embodiment by assigning the same signs as those in the first embodiment.

The base portion 110 is so resin-molded that the outer diameter D1 of the outer peripheral surface 110f gradually decreases from a rear surface 110d of a header portion 110a toward a front surface 110c (110h) of a protruding block portion 110b so that the outer shape of the base portion 110 tapers. A pawl portion 130e protruding inward from an inner side surface 130c of a sidewall portion 130a is circumferentially formed in an opening of the sidewall portion 130a of the cap portion 130, while a protrusion 130f protruding toward the opening of the cap portion 130 is formed on a region, inside a bottom surface portion 130b of the cap portion 130, opposed to the protruding block portion 110b.

The remaining structure of the semiconductor laser device 100a is similar to that of the first embodiment. A manufacturing process for the semiconductor laser device 100a is similar to the manufacturing process in the first embodiment, except the point of resin-molding the base portion 110 so that the outer peripheral surface 110f of the base portion 110 has the taper shape shown in FIG. 8 and a point of resin-molding the cap portion 130 to have the pawl portion 130e and the protrusion 130f.

The outer peripheral surface 110f of the base portion 110 has the taper shape tapering frontward from the rear portion, whereby the inner side surface 130c of the cap portion 130 can be more easily engaged with the outer peripheral surface 110f of the base portion 110 (header portion 110a). Further, the sidewall portion 130a of the cap portion 130 can be engaged while expanding/contracting the same coincidentally to the taper shape of the outer peripheral surface 110f. Thus, the inner portion of a package on which a blue-violet semiconductor laser element 20 is placed can be more reliably airtightly sealed.

Further, the protrusion 130f protruding toward the opening of the cap portion 130 is formed inside the bottom surface portion 130b of the cap portion 130, whereby when the cap portion 130 is engaged with the base portion 110, the protrusion 130f so comes into contact with the front surface 110c of the protruding block portion 110b that a clearance having a prescribed interval can be reliably formed between a light-emitting surface 20a of the blue-violet semiconductor laser element 20 and a light transmission portion 135 of the cap portion 130. In this state, the pawl portion 130e of the cap portion 130 can engage with an edge portion of the rear surface 110d of the header portion 110a while elastically deforming, whereby the cap portion 130 can be inhibited from coming out of the base portion 110 frontward (direction A1). The remaining effects of the first modification of the first embodiment are similar to those of the first embodiment.

(Second Modification of First Embodiment)

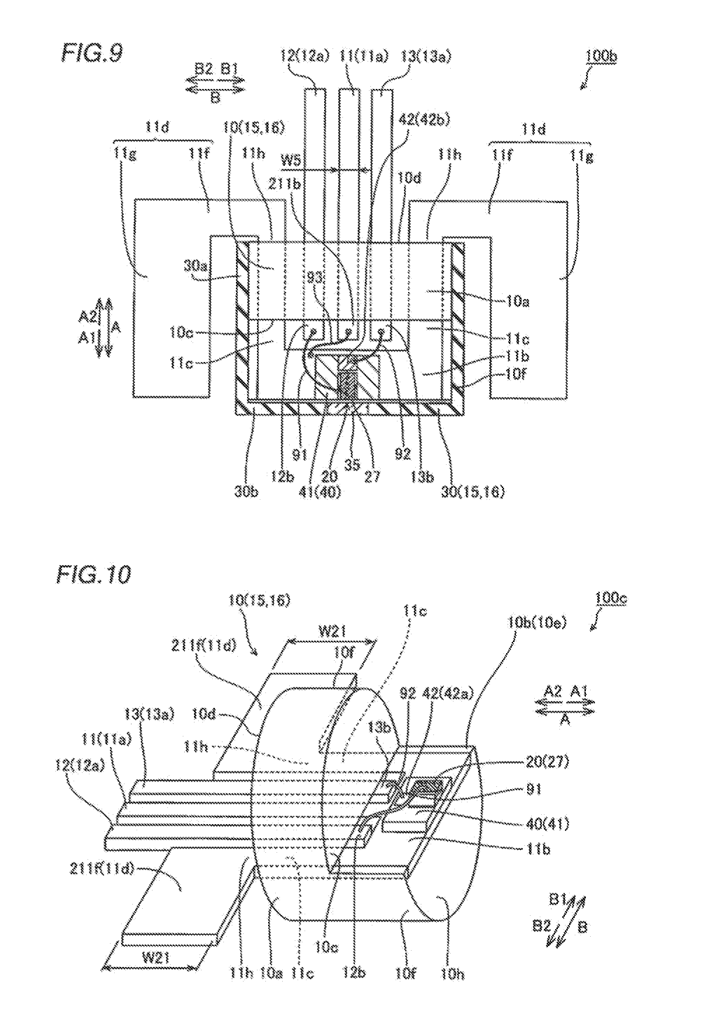

A second modification of the first embodiment is now described. In a semiconductor laser device 100b according to this second modification of the first embodiment, a front end region 11b and a lead terminal 11 are separated from each other as shown in FIG. 9, dissimilarly to the first embodiment. The figure illustrates structures similar to those in the first embodiment by assigning the same signs.

In the semiconductor laser device 100b, the lead terminal 11 and the front end region 11b separate from each other. The front region 11b and a front end portion 211b of the lead terminal 11 are electrically connected with each other through a metal wire 93 made of Au or the like. The remaining structure of the semiconductor laser device 100b is similar to that of the first embodiment.

A manufacturing process for the semiconductor laser device 100b is similar to the manufacturing process in the first modification of the first embodiment, except a point of employing a lead frame so patterned that the front end region 11b is separated from the lead terminal 11 in FIG. 6 and except a point including a step of connecting the front end region 11b with the front end portion 211b (see FIG. 9) of the lead terminal 11 by the metal wire 93 in bonding of metal wires 91 and 92. Effects of the second modification of the first embodiment are similar to those of the first modification of the first embodiment.

(Third Modification of First Embodiment)

A third modification of the first embodiment is now described. In a semiconductor laser device 100c according to this third modification of the first embodiment, heat radiation portions 11d arranged on both sides of a front end region 11b have no second heat radiation portions 11g extending frontward, as shown in FIG. 10. The figure illustrates structures similar to those in the first embodiment by assigning the same signs. Illustration of a cap portion 30 engaging with a base portion 10 is omitted.

In other words, the heat radiation portions 11d connected to rear end regions 11h of connection portions 11c are constituted of only first heat radiation portions 211f, having a width W21, extending outside the base portion 10. The width W21 is larger (W21>W3) than the width W3 (see FIG. 4) of the first heat radiation portions 11f in the first embodiment. The remaining structure of the semiconductor laser device 100c according to the third modification of the first embodiment is similar to that of the first embodiment.

As to a manufacturing process for the semiconductor laser device 100c, a lead frame is patterned to directly couple the first heat radiation portions 211f (see FIG. 10) by coupling portions 103 without forming the second heat radiation portions 11g in the first embodiment when preparing the lead frame such as that of FIG. 6. The manufacturing process other than the above is substantially similar to the manufacturing process in the first embodiment.

In the semiconductor laser device 100c, the first heat radiation portions 211f have the width W21 also in the case where the semiconductor laser device 100c has no second heat radiation portions 11g, whereby heat radiation efficiency of the heat radiation portions 11d can be easily maintained. In the semiconductor laser device 100c, no second heat radiation portions 11g are formed, whereby side portions of the base portion 10 are widely opened. Thus, a structure such as a cap portion 30 (see FIG. 1) sealing a blue-violet semiconductor laser element 20 can be more freely combined. The remaining effects of the third modification of the first embodiment are similar to those of the first embodiment.

### Second Embodiment

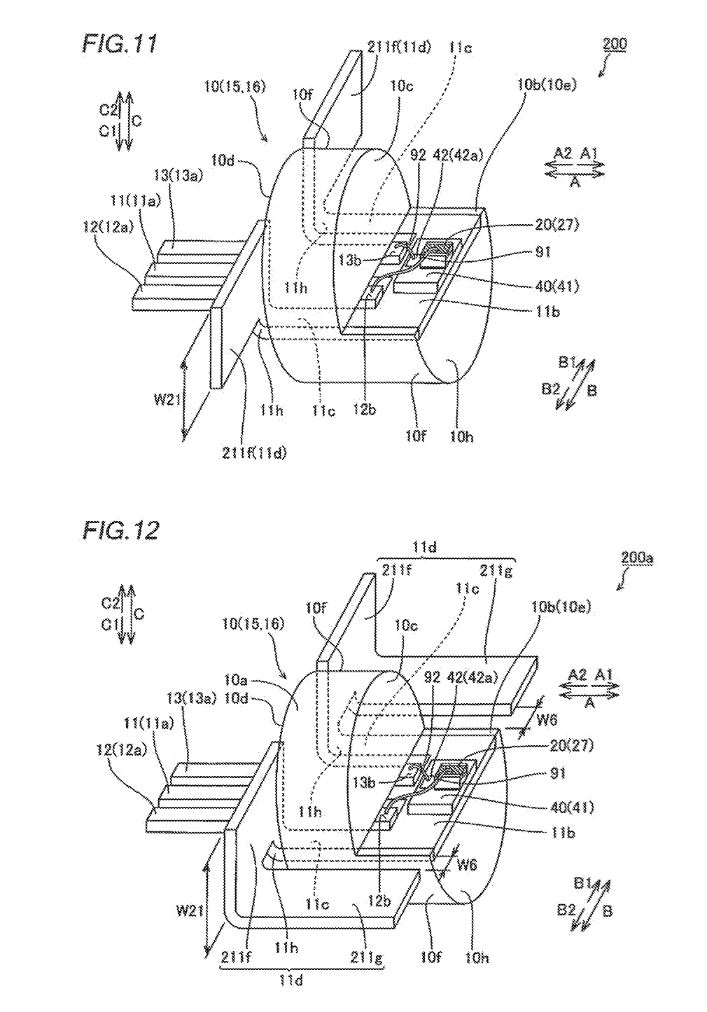

A semiconductor laser device 200 according to a second embodiment of the present invention is now described. In this semiconductor laser device 200, rear end regions 11h of connection portions 11c exposed from a rear surface 10d of a base portion 10 are arranged to be bent toward an upper side (direction C2) which is a direction substantially parallel to the rear surface 10d, as shown in FIG. 11. The remaining structure of the semiconductor laser device 200 is similar to that of the third modification of the first embodiment, and the figure illustrates structures similar to those in the third modification of the first embodiment by assigning the same signs.

A manufacturing process for the semiconductor laser device 200 is substantially similar to the manufacturing process in the third modification of the first embodiment, except that a step of bending, with respect to a lead frame having first heat radiation portions 211f, portions of the first heat radiation portions 211f toward the upper side substantially orthogonal to the upper surface of the lead frame by an unshown pressing machine or the like is added.

The rear end regions 11h of the connection portions 11c are bent toward the upper side (direction C2), whereby heat radiation portions 11d (first heat radiation portions 211f) can be easily extended and arranged in an upper direction (direction C). Thus, the surface areas of the heat radiation portions 11d (first heat radiation portions 211f) can be easily increased. Therefore, heat radiation efficiency of the heat radiation portions 11d can be easily maintained, whereby heat radiation characteristics can be further improved.

Further, the rear end regions 11h are bent toward the upper side, whereby the heat radiation portions 11d extend substantially parallelly to the rear surface 10d. In other words, the surface areas of the heat radiation portions 11d (first heat radiation portions 211f) can be easily increased without changing the length in the total length direction (direction A) of the semiconductor laser device 200. The remaining effects of the second embodiment are similar to those of the first embodiment.

(Modification of Second Embodiment)

A semiconductor laser device 200a according to a modification of the second embodiment is now described. This semiconductor laser device 200a includes a similar structure as compared with the semiconductor laser device 200 according to the second embodiment, except that second heat radiation portions 211g extending frontward from upwardly bent first heat radiation portions 211f are formed, as shown in FIG. 12. The figure illustrates structures similar to those in the second embodiment by assigning the same signs.

In other words, the second heat radiation portions 211g having a width W4 are connected to the first heat radiation portions 211f of heat radiation portions 11d and the first heat radiation portions 211f. These second heat radiation portions 211g are connected to end portions on the opposite side of the first heat radiation portions 211f to sides to which connecting portions 11c are connected. Further, the second heat radiation portions 211g are bent frontward (direction A1) on regions connected to the first heat radiation portions 211f. In addition, the second heat radiation portions 211g are arranged to extend frontward (direction A1) on the same plane as a front end region 11b of a lead terminal 11 and connection portions 11c, to be separated from an outer peripheral surface 10f of a base portion 10 by a distance W6.

A manufacturing process for the semiconductor laser device 200a is similar to the manufacturing process in the second embodiment, except that the width of the first heat radiation portions 211f is enlarged to W21 in the manufacturing process in the aforementioned first embodiment and that a step of bending portions of the first heat radiation portions 211f upward with respect to the upper surface of a lead frame with an unshown pressing machine or the like is added after preparing the lead frame such as that of FIG. 6.

The second heat radiation portions 211g extending frontward are formed in addition to the first heat radiation portions 211f extending upward, whereby the surface areas of the heat radiation portions 11d are more increased than the case of the aforementioned second embodiment. Therefore, heat radiation efficiency of the heat radiation portions 11d can be further improved. The remaining effects of the modification of the second embodiment are similar to those of the second embodiment.

### Third Embodiment

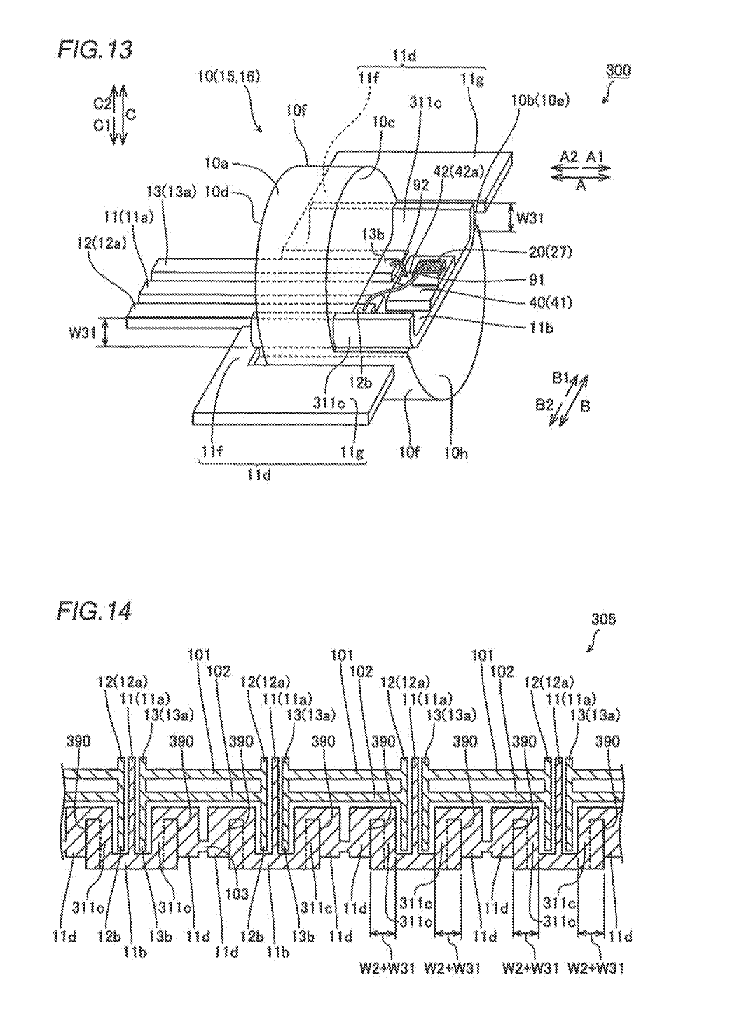

A semiconductor laser device 300 according to a third embodiment is now described. This semiconductor device 300 includes a similar structure to the semiconductor laser device 100 except that end regions of connection portions 311c are bent upward (direction C2) as shown in FIG. 13, and the figure illustrates structures similar to those in the first embodiment by assigning the same signs.

In the semiconductor laser device 300, the connection portions 311c having a larger width than the connection portions 11c in the first embodiment are provided between a front end region 11b of a lead terminal 11 and respective heat radiation portions 11d. More specifically, end regions (regions of the respective connection portions 311c on a B2 side or a B1 side) of the connection portions 311c along a direction B are bent in a direction (height direction (direction C2) of a blue-violet semiconductor laser element 20) substantially orthogonal to the upper surface of the front end region 11b. At this time, end portions (on the B2 side and on the B1 side) of the front end region 11b to which the connection portions 311c are connected are also bent in the direction C2. The connection portions 311c completely pass through a base portion 10 in a direction A2 in the state where the end regions are bent in the direction C2.

Therefore, the connection portions 311c have the width W31 of the end regions extending upward in addition to the width W2 (see FIG. 4) of the connection portions 11c of the first embodiment, thereby having a width (peripheral length along the upper surfaces of the connection portions 311c) of W2+W31 in total. Thus, in a case where the connection portions 311c is observed along the direction A2 in FIG. 13, the cross sections thereof increase beyond those of the connection portions 11c (see FIG. 1).

As to a manufacturing process for the semiconductor laser device 300, a lead frame 305 in which substantially L-shaped notching lines 390 are formed between connection portions 311c and heat radiation portions 11d is formed as shown in FIG. 14, while a step of bending the front end region 11b and the end regions of the connection portions 311c upward with respect to the upper surface of the lead frame by an unshown pressing machine or the like is added. The remaining manufacturing process is substantially similar to the manufacturing process in the first embodiment.

In the semiconductor laser device 300, the end regions of the connection portions 311c are bent in the direction C2. Thus, cross sections perpendicular to the direction A where the connection portions 311c extend can be easily increased, whereby heat resistance in the connection portions 311c so decreases that heat can be rendered easily transmittable. Consequently, heat radiation efficiency of the heat radiation portions 11d can be further improved.

Further, the end regions of the connection portions 311c are bent upward, whereby rigidity of the connection portions 311c can be improved. The remaining effects of the third embodiment are similar to those of the first embodiment.

### Fourth Embodiment

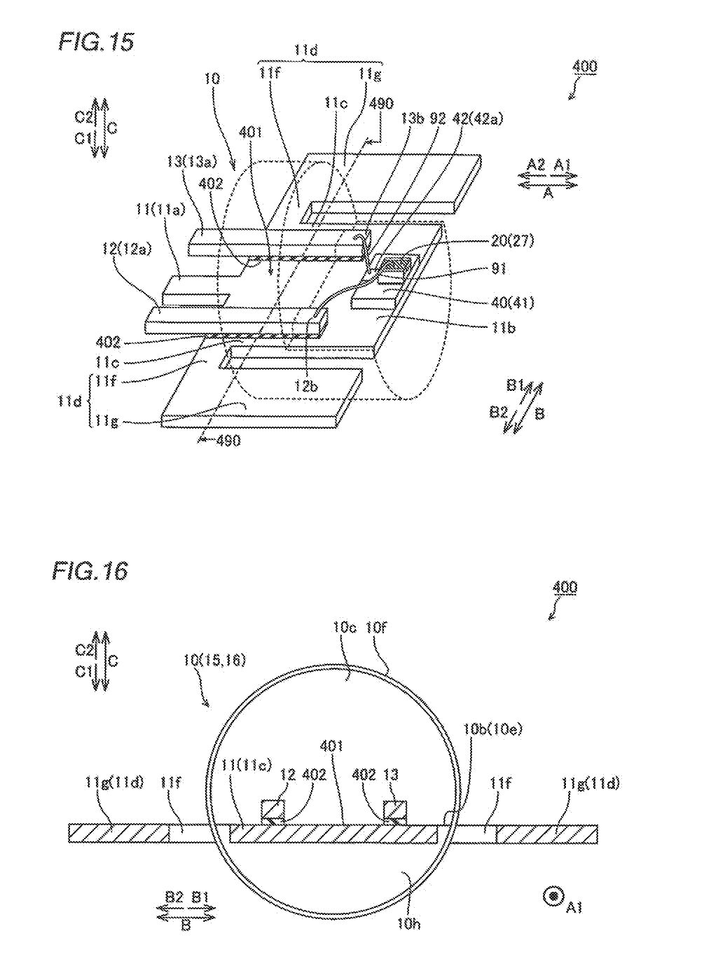

A fourth embodiment is described with reference to FIGS. 15 to 17. In a semiconductor laser device 400 according to this fourth embodiment, such a case where a lead terminal 11 and lead terminals 12 and 13 are formed on different height positions dissimilarly to the first embodiment is described. FIG. 15 shows an outer shape of a base portion 10 (see FIG. 16) with broken lines, in order to illustrate a detailed structure of a lead frame. FIG. 16 is a diagram observing the base portion 10 on a cross section along the line 490-490 in FIG. 15. The figures illustrate structures similar to those in the first embodiment by assigning the same signs. The lead terminals 12 and 13 are examples of the “second lead terminal” in the present invention.

In the semiconductor laser device 400, referring to FIG. 1, no notched portion surrounded by the lead terminal 11, the connection portions 11c and the front end region 11b shown in the first embodiment is formed. In other words, a substantially rectangular plane portion 401 including the front end region 11b and the connection portions 11c is formed on the lead terminal 11 of the semiconductor laser device 400, as shown in FIG. 15. On a rear side (direction A2) of the plane portion 401, heat radiation portions 11d are connected to the plane portion 401. As shown in FIG. 16, lead terminals 12 and 13 are formed on a plane in a height direction (direction C) different from the lead terminal 11 (front end region 11b) through insulating films 402 made of epoxy resin formed on the plane portion 401. Therefore, the plane portion 401 (lead terminal 11) and the lead terminals 12 and 13 pass through the base portion 10 from a front side (A1 side) toward the rear side (A2 side) in a state insulated from each other and on respective positions different from each other also in the height direction. The remaining structure of the semiconductor laser device 400 is similar to that of the first embodiment.

In a manufacturing process for the semiconductor laser device 400, a lead frame 106 in which lead terminals 11 are repeatedly patterned in a lateral direction (direction B) is first formed by etching a belt-shaped metal plate as shown in FIG. 17, similarly to the first embodiment. At this time, referring to FIG. 6, no patterning is performed as to lead terminals 12 and 13. Further, the lead frame 106 is patterned in a state where first heat radiation portions 11f are directly connected to rear portions of plane portions 401 without forming notched portions surrounded by lead terminals 11, connection portions 11c and front end regions 11b. Referring to FIG. 6, a lead frame 107 in which lead terminals 12 and 13 are repeatedly patterned in the lateral direction (direction B) is separately formed.

Thereafter insulating films 402 (see FIG. 16) made of epoxy resin are applied onto prescribed regions of the plane portions 401 where the lead terminals 12 and 13 are arranged. Then, the epoxy resin is hardened in a state arranging the lead frame 107 on the lead frame 106 so that the lead terminals 12 and 13 overlap on the surfaces of the insulating films 402. Thus, the lead frame 106 is bonded to the lead frame 107 (see FIG. 17). Thereafter base portions 10 are molded to fix the lead terminals 11, 12 and 13, as shown in FIGS. 15 and 16. The remaining manufacturing process in the fourth embodiment is substantially similar to the manufacturing process in the first embodiment.

The front end region 11b and the lead terminals 12 and 13 are arranged on different planes. Thus, the number of the lead terminals can be easily increased without reducing the width of the lead terminals. Further, the width (cross section) of the plane portion 401 can be properly ensured also in a case of increasing the number of the lead terminals, whereby heat radiation (heat transfer) characteristics can be inhibited from lowering when radiating heat from the front end region 11b to the heat radiation portions 11d through the plane portion 401. The remaining effects of the fourth embodiment are similar to those of the first embodiment.

### Fifth Embodiment

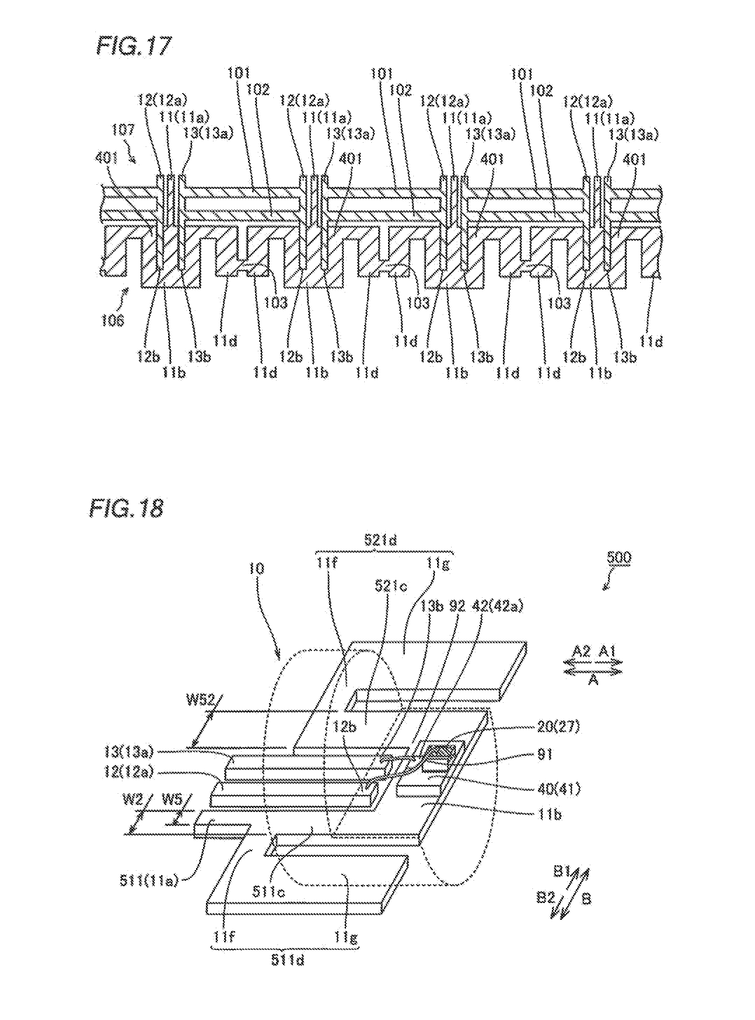

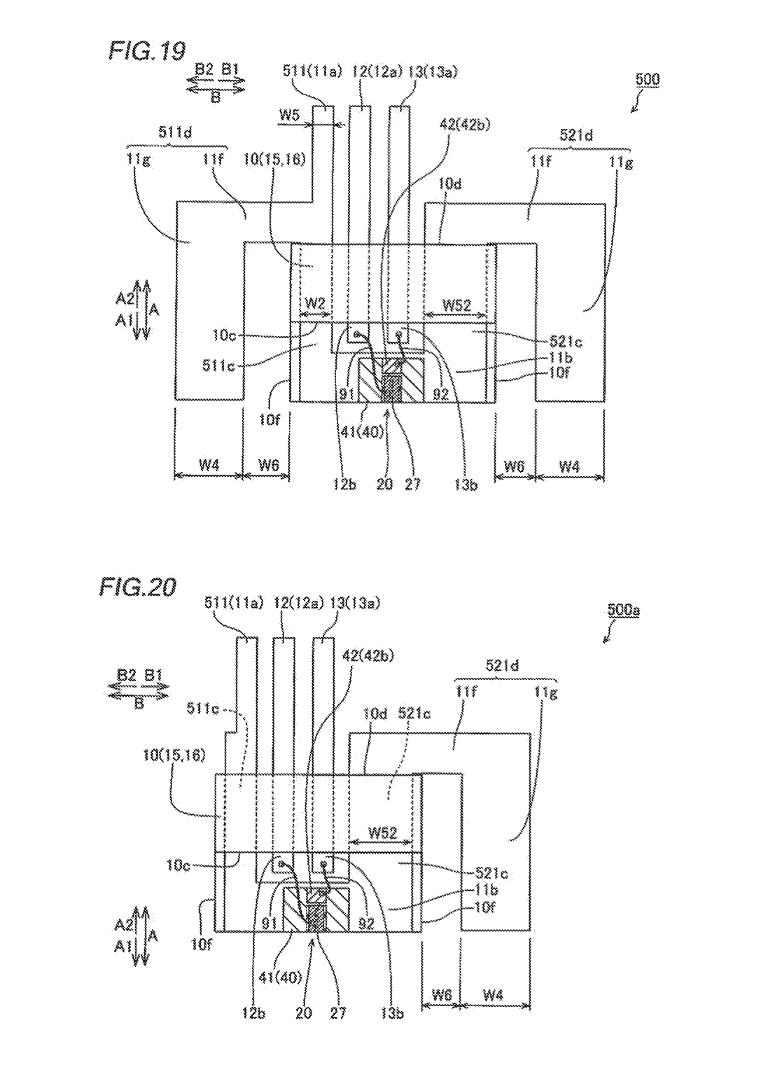

A fifth embodiment is described with reference to FIGS. 18 and 19. In a semiconductor laser device 500 according to this fifth embodiment, one connection portion 511c serves also as a lead terminal 511, dissimilarly to the first embodiment. FIG. 18 shows an outer shape of a base portion 10 (see FIG. 19) mounted with a front end region 11b with broken lines, in order to illustrate a detailed structure of a lead frame. The figures illustrate structures similar to those in the first embodiment by assigning the same signs. The lead terminal 511 is an example of the “first lead terminal” in the present invention.

In the semiconductor laser device 500, the lead terminal 511 having a width W5 extends rearward from a rear end portion (A2 side) of one (B2-side) connection portion 511c having a width W2, as shown in FIGS. 18 and 19. A heat radiation portion 511d is connected to a rear end portion of the connection portion 511c. Lead terminals 12 and 13 are provided between another (B1 side) connection portion 521c having a width W52 and the connection portion 511c.

As shown in FIG. 19, the width W52 of the connection portion 521c is larger (W52>W2) than the width W2 of the connection portion 511c. In other words, the structure on the side (2 side) of the connection portion 511c and the structure on the side (B1 side) of the connection portion 521c are asymmetrical with respect to a blue-violet semiconductor laser element 20 in plan view, as shown in FIG. 19. The remaining structure of the semiconductor laser device 500 is similar to that of the first embodiment.

A manufacturing process for the semiconductor laser device 500 is substantially similar to the manufacturing process in the first embodiment, except a point of forming a lead frame so patterned that lead terminals 12 and 13 are arranged on regions between lead terminals 511 having connection portions 511c and 521c asymmetrically arranged in the lateral direction with respect to substantial centers of front end regions 11b and connection portions 511c and 521c is formed.

The connection portion 511c on one side (B2 side) and the lead terminal 511 are formed in common, whereby the width W52 of the connection portion 521c of the heat radiation portion 521d on the other side (B1 side) can be formed to be larger. Consequently, heat radiation efficiency of the heat radiation portion 521d can be improved. The remaining effects of the fifth embodiment are similar to those of the first embodiment.

(Modification of Fifth Embodiment)

A modification of the fifth embodiment is now described. A semiconductor laser device 500a according to this modification of the fifth embodiment includes a similar structure, as compared with the semiconductor laser device 500 according to the fifth embodiment, except that no heat radiation portion 511d is formed as shown in FIG. 20, and the figure illustrates structures similar to those in the fifth embodiment by assigning the same signs.

As shown in FIG. 20, no heat radiation portion 511d (see FIG. 18) shown in the fifth embodiment is formed on a lead terminal 511, but only a heat radiation portion 521d is formed on one side (B1 side). The remaining structure of the semiconductor laser device 500a is similar to that of the first embodiment. A manufacturing process for the semiconductor laser device 500a is substantially similar to the manufacturing process in the fifth embodiment, except a point of preparing a lead frame in which connection portions 521c and heat radiation portions 521d consisting of only first heat radiation portions 11f and second heat radiation portions 11g are formed on one side.

Also when including the heat radiation portion 521d only on one side (B1 side) of the lead terminal 511 as the semiconductor laser device 500a, heat generated by a blue-violet semiconductor laser element 20 can be radiated from the heat radiation portion 521d to the exterior through the connection portion 521c. Thus, the width (direction B) of the semiconductor laser device 500a can be easily reduced. In this case, the width (width in the direction B) of the connection portion 521c to which the heat radiation portion 521d is connected is formed to be larger than the connection portions 11c of the first embodiment, whereby heat can be sufficiently radiated even if the heat radiation portion 521d is formed only on one side. The remaining effects of the modification of the fifth embodiment are similar to those of the first embodiment.

### Sixth Embodiment

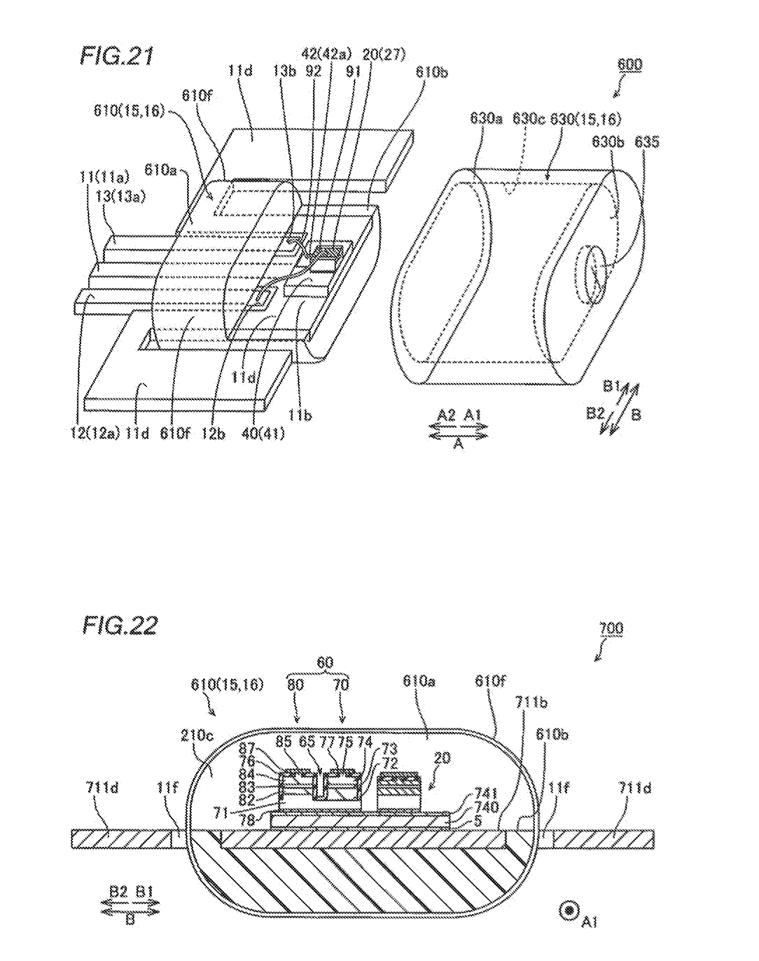

A sixth embodiment is described with reference to FIG. 21. A semiconductor laser device 600 according to this sixth embodiment has a base portion 610 having such a rounded-rectangle shape that sections of a header portion 610a and a protruding block portions 610b are elongated in the width direction (direction B) while no edges (corner portions) or the like are formed on outer peripheral surfaces 610f on both end portions of the base portion 610 in the direction B. Also a cap portion 630 is so resin-molded that a bottom surface portion 630b and the inner periphery of a sidewall portion 630a tubularly extending from the bottom surface portion 630b have sections corresponding to the cross-sectional shape (rounded-rectangle shape) of the base portion 610 (header portion 610a). Thus, an inner side surface 630c of the cap portion 630 engages in a state completely surrounding the outer peripheral surfaces 610f of the base portion 610. The figure illustrates structures similar to those in the first embodiment by assigning the same signs as the first embodiment.

The cap portion 630 is made of a mixture of a gas absorbent consisting of particulate synthetic zeolite and thermoplastic fluororesin having elasticity. The gas absorbent is preferably mixed in the range of at least about 40 weight % and not more than about 70 weight % with respect to the thermoplastic fluororesin. The thermoplastic fluororesin is an example of the “resin” in the present invention.

At a central portion of the bottom surface portion 630b having the rounded-rectangle shape, a light transmission portion 635 where a laser beam emitted from a blue-violet semiconductor laser element 20 is transmittable toward the exterior is formed integrally with the cap portion 630. While the light transmission portion 635 contains no gas absorbent and hence has translucency, the sidewall portion 630a and the bottom surface portion 630b contain the gas absorbent and hence have no translucency.

Also in the sixth embodiment, a gas barrier layer 17 (see FIG. 2) for blocking external penetration of gas is formed on the outer peripheral surfaces 610f and a rear surface 610d of the base portion 610, and a gas barrier layer 33 is formed on the sidewall portion 630a of the cap portion 630 and an outer surface 630d of the bottom surface portion 630b.

When describing a manufacturing process for the cap portion 630, gas absorbent consisting of synthetic zeolite pulverized to have a particle diameter of at least several 10 μm and not more than several 100 μm is mixed into thermoplastic fluororesin in the form of a pellet (columnar particles having a length of about 3 to 5 mm). The mixture of the thermoplastic fluororesin and the gas absorbent is kneaded by employing a kneader while heating the same under a temperature condition of about 170° C. At this time, the ratio of the gas absorbent to the thermoplastic fluororesin is preferably set to at least about 40% and not more than about 70%.

Thereafter the kneaded substance of the thermoplastic fluororesin and the gas absorbent is poured into a mold (not shown) having a prescribed shape and hardened by cooling. Thus, the sidewall portion 630a of the cap portion 630 and the bottom surface portion 630b (see FIG. 21) in which an opening is formed in a substantially central portion are molded. At this time, heat treatment is more preferably performed on the gas absorbent before mixing the gas absorbent into the thermoplastic fluororesin. Thus, absorbability of the gas absorbent is improved.

Thereafter thermoplastic fluororesin into which no gas absorbent is mixed and the cap portion 630 (portions of the sidewall portion 630a and the bottom surface portion 630b) molded in the aforementioned step are introduced into the mold (not shown) having the prescribed shape again, and heated under a temperature condition of about 170° C. Thus, the light transmission portion 635 (see FIG. 21) having translucency is molded in the opening having been formed in the substantially central portion of the aforementioned bottom surface portion 630b. Volatile gas from the thermoplastic fluororesin forms no incrustation on a facet, and hence no degassing performed in the manufacturing process for the cap portion 30 in the first embodiment may be performed.

The remaining structure of the semiconductor laser device 600 is similar to that of the first embodiment. Further, the remaining manufacturing process for the semiconductor device 600 is substantially similar to that of the first embodiment except a point of resin-molding the base portion 610 in which the header portion 610a and the protruding block portion 610b are elongated in the width direction (direction B) to correspond to the cross-sectional shape (rounded rectangle shape) of the cap portion 630.

The base portion 610 and the cap portion 630 are made of the mixtures of the epoxy resin with the gas absorbent and the thermoplastic fluororesin with the gas absorbent respectively. Thus, volatile organic gas generated from the resin of the base portion 610 and the cap portion 630 can be absorbed by the gas absorbent.

In order to confirm usefulness of the employment of the thermoplastic fluororesin for the cap portion, the following experiment was conducted: First, a light transmission portion 635 was prepared from thermoplastic fluororesin (by Minnesota Mining and Manufacturing Co.: THV500G) consisting of tetrafluoroethylene, hexafluoropropylene and vinylidene fluoride having a thickness of about 1 mm, and this was arranged at a distance of 1 mm from a light-emitting surface 20a. Then, when a laser beam from a blue-violet semiconductor laser element 20 adjusted to an output of 10 mW by APC was applied to the aforementioned light transmission portion 635 for 1000 hours under a condition of 70° C., it was confirmed that the transmittance of the light transmission portion 635 remained unchanged. From this result, the usefulness of the employment of the thermoplastic fluororesin for the cap portion 630 was confirmed.

Further, only the blue-violet semiconductor laser element 20 was mounted on a stem (base portion) of a metal having a diameter (outer diameter) of 9 mm. When putting a cap portion (provided with a glass window) of a metal thereon and performing sealing, thermoplastic fluororesin (by Minnesota Mining and Manufacturing Co.: THV500G) cut into sizes of 2 mm×2 mm×0.1 mm (length×width×thickness) was introduced into a package and sealed. Then, an operating test was conducted by emitting a laser beam adjusted to an output of 10 mW by APC from the blue-violet semiconductor laser element 20 under a condition of 70° C. Consequently, no remarkable change was caused in operating current also after a lapse of 250 hours. As comparative example, an operating test was conducted after introducing an acrylic plate cut into the same sizes as the above into the same package and sealing the same. In this case, operating current started to rise in 140 hours, and a laser element was broken.

No incrustation is formed on a light-emitting facet by volatile gas from the thermoplastic fluororesin, and hence deterioration of the blue-violet semiconductor laser element 20 can be further suppressed in the semiconductor laser device 600 in which the cap portion 630 is formed by this thermoplastic fluororesin. Further, no degassing may be performed as to the thermoplastic fluororesin, whereby the semiconductor laser device 600 having excellent characteristics can be easily manufactured. The remaining effects of the semiconductor laser device 600 according to the sixth embodiment are similar to those of the first embodiment.

### Seventh Embodiment

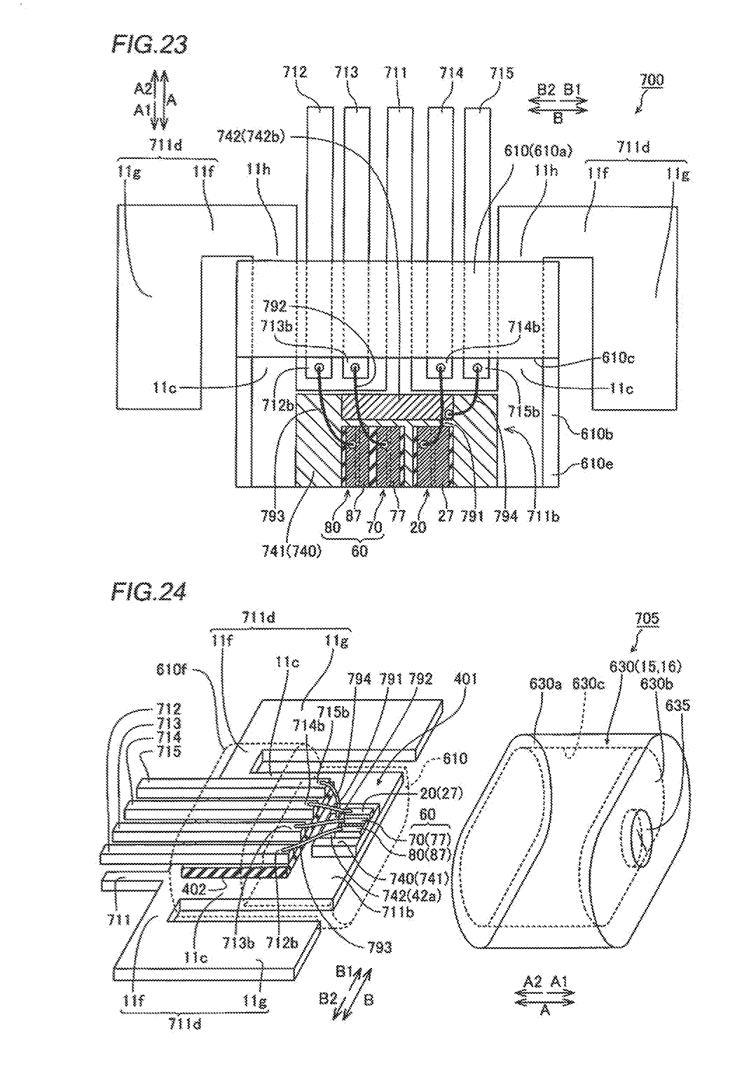

First, a seventh embodiment is described with reference to FIGS. 22 and 23. In a three-wavelength semiconductor laser device 700 according to this seventh embodiment, an integrated semiconductor laser device is constituted by loading a plurality of semiconductor laser elements emitting laser beams of wavelengths different from each other, dissimilarly to the sixth embodiment. The figures illustrate structures similar to those in the sixth embodiment by assigning the same signs as the sixth embodiment.

The three-wavelength semiconductor laser device 700 has such a structure that each of the blue-violet semiconductor laser element 20 of the first embodiment and a two-wavelength semiconductor laser element 60 in which a red semiconductor laser element 70 having a lasing wavelength of about 650 nm and an infrared semiconductor laser element 80 having a lasing wavelength of about 780 nm are monolithically formed is bonded onto the surface of a conductive submount 740 made of Al through a pad electrode 741 in a state adjacent to each other in the lateral direction (direction B), as shown in FIG. 22. The submount 740 is bonded to the surface of a lead terminal 711 (front end region 711b) exposed from a base portion 610 through a conductive adhesive layer 5. The three-wavelength semiconductor laser device 700 is so formed that the cap portion 630 is engaged with and put on the base portion 610 and a package is airtightly sealed. The three-wavelength semiconductor laser device 700 is an example of the “semiconductor light-emitting device” in the present invention. The two-wavelength semiconductor laser element 60, the red semiconductor laser element 70 and the infrared semiconductor laser element 80 are examples of the “semiconductor light-emitting element” in the present invention.

On the base portion 610, lead terminals 711, 712, 713, 714 and 715 consisting of a lead frame of a metal are arranged on the same plane to pass through a header portion 610a in a state insulated from each other, as shown in FIG. 23. The lead terminal 711 passes through a substantial center of the header portion 610a. The lead terminals 712 and 713 and the lead terminals 714 and 715 are arranged on respective outer sides (on a B2 side and on a B1 side) of the lead terminal 711 in the width direction (direction B). The lead terminals 711 to 715 have front-side (A1 side) front end regions 711b to 715b respectively. The front end regions 715b to 715b are exposed from a front surface 610c of the header portion 610a, and arranged on an upper surface 610e of a protruding block portion 610b. The front end region 711b of the lead terminal 711 spreads in the direction B on the protruding block portion 610b. The blue-violet semiconductor laser element 20 and the two-wavelength semiconductor laser element 60 are fixed to a substantial center of the front end region 711b. The front end region 711b is an example of the “element placement portion” in the present invention.

A pair of heat radiation portions 711d formed on the lead terminal 711, which extend toward the B2 side and the B1 side after a passage through the header portion 610a rearward (direction A2) on outer sides (on the B2 side and on the B1 side) of the lead terminals 712 and 715 from both end portions of the front end region 711b in the direction B on the same plane as the lead terminals 711 to 715, separate from an outer peripheral surface 610f of the base portion 610 and thereafter extend toward the front side (direction A1) again. Further, the width of the heat radiation portions 711d in the direction B is formed to be larger than the width of a portion of the lead terminal 711 passing through the header portion 610a. Therefore, heat generated by the blue-violet semiconductor laser element 20 and the two-wavelength semiconductor laser element 60 operating in a package radiates to the exterior of the three-wavelength semiconductor laser device 700 through the submount 740, the front end region 711b and the heat radiation portions 711d on both sides.

In the two-wavelength semiconductor laser element 60, the red semiconductor laser element 70 and the infrared semiconductor laser element 80 are formed on the surface of a common n-type GaAs substrate 71 through a recess portion 65 having a prescribed groove width, as shown in FIG. 22.

More specifically, an n-type cladding layer 72 made of AlGaInP, an active layer 73 having such an MQW structure that quantum well layers made of GalnP and barrier layers made of AlGaInP are alternately stacked and a p-type cladding layer 74 made of AlGaInP are formed on the upper surface of an n-type GaAs substrate 71 in the red semiconductor laser element 70. Further, a current blocking layer 76 made of SiO₂ covering the upper surface of the p-type cladding layer 74 other than a ridge 75 and both side surfaces of the ridge 75 is formed. A p-side electrode 77 in which a Pt layer having a thickness of about 200 nm and an Au layer having a thickness of about 3 μm are stacked is formed on the upper surfaces of the ridge 75 and the current blocking layer 76. An n-side electrode 78 in which an AuGe layer, an Ni layer and an Au layer are stacked in this order in order close to the n-type GaAs substrate 71 is formed on the lower surface of the n-type GaAs substrate 71. The n-side electrode 78 is provided as an n-side electrode common to the red semiconductor laser element 70 and the infrared semiconductor laser element 80.

In the red semiconductor laser element 80, an n-type cladding layer 82 made of AlGaAs, an active layer 83 having such an MQW structure that quantum well layers made of AlGaAs having a low Al composition and barrier layers made of AlGaAs having a high Al composition are alternately stacked and a p-type cladding layer 84 made of AlGaAs are formed on the upper surface of the n-type GaAs substrate 71. Further, a current blocking layer 86 made of SiO₂ covering the upper surface of the p-type cladding layer 84 other than a ridge 85 and both side surfaces of the ridge 85 is formed. A p-side electrode 87 is formed on the upper surfaces of the ridge 85 and the current blocking layer 86.

As shown in FIG. 23, the blue-violet semiconductor laser element 20 is connected to the front end region 714b of the lead terminal 714 through a metal wire 791 wire-bonded to the p-side electrode 27. The red semiconductor laser element 70 is connected to the front end region 713b of the lead terminal 713 through a metal wire 792 wire-bonded to the p-side electrode 77. The infrared semiconductor laser element 80 is connected to the front end region 712b of the lead terminal 712 through a metal wire 793 wire-bonded to the p-side electrode 87. A monitoring PD 742 formed to be capable of receiving each laser beams from light-reflecting surfaces of the laser elements is connected to the front end region 715b of the lead terminal 715 through a metal wire 794 wire-bonded to a p-type region 742b. The n-side electrode 28 of the blue-violet semiconductor laser element 20, the n-side electrode 78 of the two-wavelength semiconductor laser element 60 and an n-type region (not shown) of the monitoring PD 742 are electrically connected to the lead terminal 711 through the submount 740 together.

The remaining structure of and a manufacturing process for the three-wavelength semiconductor laser device 700 are substantially similar to those in the sixth embodiment except a point of bonding the blue-violet semiconductor laser element 20 and the two-wavelength semiconductor laser element 60 to the submount 740 in a state aligning the same with each other in the lateral direction (direction B in FIG. 23). Further, effects of the three-wavelength semiconductor laser device 700 are similar to those of the sixth embodiment.

(Modification of Seventh Embodiment)

A modification of the seventh embodiment is described with reference to FIGS. 22 and 24. In a three-wavelength semiconductor laser device 705 according to this modification of the seventh embodiment, a lead terminal 711 and lead terminals 712 to 715 are formed on different height positions, dissimilarly to the seventh embodiment. In other words, the lead terminals 712 to 715 are formed on a different plane from the lead terminal 711 (front end region 711b) in the height direction (direction C) through insulating films 402 made of epoxy resin formed on a plane portion 401. Therefore, the plane portion 401 (lead terminal 711) and the lead terminals 712 to 715 pass through a base portion 610 from a front side (A1 side) rearward (A2 side) in a state insulated from each other and on respective positions different from each other also in the height direction. The lead terminals 712 to 715 are examples of the “second lead terminal” in the present invention.

As shown in FIG. 24, one (B2-side) connection portion 711c serves also as the lead terminal 711. FIG. 24 shows the outer shape of the base portion 610 mounted with the front end region 711b with broken lines, in order to illustrate the detailed structure of lead terminals bonded onto a lead frame. The remaining structure of the semiconductor laser device 705 is similar to that of the seventh embodiment.

A manufacturing process in the modification of the seventh embodiment is substantially similar to the manufacturing process in the seventh embodiment.

The front end region 711b and the lead terminals 712 to 715 are arranged on different planes. Thus, the three-wavelength semiconductor laser device 705 capable of easily increasing the number of lead terminals can be obtained without reducing the width of the lead terminals. The remaining effects of the modification of the seventh embodiment are similar to those of the seventh embodiment.

### Eighth Embodiment

An optical pickup device 850 according to an eighth embodiment of the present invention is described with reference to FIGS. 23 and 25. The optical pickup device 850 is an example of the “optical device” in the present invention.

The optical pickup device 850 includes the three-wavelength semiconductor laser device 700 (see FIG. 23) according to the seventh embodiment, an optical system 820 adjusting laser beams emitted from the three-wavelength semiconductor laser device 700 and a light detection portion 830 receiving the laser beams, as shown in FIG. 25.

The optical system 820 has a polarizing beam splitter (PBS) 821, a collimator lens 822, a beam expander 823, a λ/4 plate 824, an objective lens 825, a cylindrical lens 826 and an optical axis correction device 827, as shown in FIG. 25.

The PBS 821 totally transmits the laser beams emitted from the three-wavelength semiconductor laser device 700, and totally reflects the laser beams fed back from an optical disk 835. The collimator lens 822 converts the laser beams from the three-wavelength semiconductor laser device 700 transmitted through the PBS 821 to parallel beams. The beam expander 823 is constituted of a concave lens, a convex lens and an actuator (not shown). The actuator has a function of correcting wave-front states of the laser beams emitted from the three-wavelength semiconductor laser device 700 by changing the distance between the concave lens and the convex lens in response to a servo signal from a servo circuit described later.

The λ/4 plate 824 converts linear polarization of the laser beams converted to substantially parallel beams by the collimator lens 822 to circular polarization. Further, the λ/4 plate 824 converts circular polarization of the laser beams fed back from the optical disk 835 to linear polarization. The direction of polarization of the linearly polarized beams in this case is orthogonal to the direction of the linear polarization of the laser beams emitted from the three-wavelength semiconductor laser device 700. Thus, the laser beams fed back from the optical disk 835 are substantially totally reflected by the PBS 821. The laser beams transmitted through the λ/4 plate 824 converges on the surface (recording layer) of the optical disk 835 by the objective lens 825. The objective lens 825 is rendered by an objective lens actuator (not shown) movable in a focusing direction, a tracking direction and a tilting direction in response to servo signals (a tracking servo signal, a focusing servo signal and a tilting servo signal) from the servo circuit described later.

The cylindrical lens 826, the optical axis correction device 827 and the light detection portion 830 are arranged so as to be along the optical axes of the laser beams totally reflected by the PBS 821. The cylindrical lens 826 supplies astigmatic action to the incident laser beams. The optical axis correction device 827 is constituted of a diffraction grating, and so arranged that spots of zeroth-order diffracted beams of laser beams of blue-violet, red and infrared transmitted through the cylindrical lens 826 coincide with each other on a detection region of the light detection portion 830 described later.

The light detection portion 830 outputs a playback signal on the basis of intensity distribution of the received laser beams. The light detection portion 830 has a detection region of a prescribed pattern so that an focusing error signal, a tracking error signal and a tilting error signal are obtained along with the playback signal. The optical pickup device 850 including the three-wavelength semiconductor laser device 700 is constituted in this manner.

In this optical pickup device 850, the three-wavelength semiconductor laser device 700 is formed to be capable of independently emitting the laser beams of blue-violet, red and infrared from a blue-violet semiconductor laser element 20, a red semiconductor laser element 70 and an infrared semiconductor laser element 80 by independently applying a voltage between the lead terminal 711 and the lead terminals 712 to 714. The laser beams emitted from the three-wavelength laser device 700 are adjusted by the PBS 821, the collimator lens 822, the beam expander 823, the λ/4 plate 824, the objective lens 825, the cylindrical lens 826 and the optical axis correction device 827, and thereafter applied onto the detection region of the light detection portion 830.

In a case of playing back information recorded in the optical disk 835, the laser beams are applied to the recording layer of the optical disk 835 while controlling the laser power emitted from the blue-violet semiconductor laser element 20, the red semiconductor laser element 70 or the infrared semiconductor laser element 80 so as to be constant, and the playback signal output from the light detection portion 830 can be obtained. Further, the actuator of the beam expander 823 and the objective lens actuator driving the objective lens 825 can be feedback-controlled with the focusing error signal, the tracking error signal and the tilting error signal outputted at the same time.

In a case of recording information in the optical disk 835, the laser beams are applied to the optical disk 835 while controlling laser power emitted from the blue-violet semiconductor laser element 20 or the red semiconductor laser element 70 (infrared semiconductor laser element 80) on the basis of the information to be recorded. Thus, the information can be recorded in the recording layer of the optical disk 835. Further, the actuator of the beam expander 823 and the objective lens actuator driving the objective lens 825 can be feedback-controlled with the focusing error signal, the tracking error signal and the tilting error signal outputted from the light detection portion 830, similarly to the above.

Thus, recording in and playback from the optical disk 835 can be performed by the optical pickup device 850 including the three-wavelength semiconductor laser device 700.

The optical pickup device 850 includes the three-wavelength semiconductor laser device 700 in the seventh embodiment, whereby the optical pickup device 850 having high reliability capable of withstanding long-time use, in which the individual semiconductor laser elements loaded on the three-wavelength semiconductor laser device 700 are inhibited from deterioration, can be obtained due to excellent heat radiation properties possessed by the three-wavelength semiconductor laser device 700. In addition, the optical pickup device 850 in which the size of the three-wavelength laser device 700 is inhibited from enlargement can be obtained.

### Ninth Embodiment

An optical disk device 900 according to a ninth embodiment of the present invention is described with reference to FIGS. 25 and 26. The optical disk device 900 is an example of the “optical device” in the present invention.

The optical disk device 900 includes the optical pickup device 850 according to the eighth embodiment, a controller 901, a laser driving circuit 902, a signal generation circuit 903, a servo circuit 904 and a disk driving motor 905, as shown in FIG. 26.

Record data S1 generated on the basis of information to be recorded in an optical disk 835 is input in the controller 901. The controller 901 outputs signals S2 and S7 toward the laser driving circuit 902 and the servo circuit 904 respectively in response to the record data S1 and a signal S5 from the signal generation circuit 903 described later. Further, the controller 901 outputs playback data S10 on the basis of the signal S5, as described later. The laser driving circuit 902 outputs a signal S3 controlling laser power emitted from a three-wavelength semiconductor laser device 700 in the optical pickup device 850 in response to the signal S2. In other words, the controller 901 and the laser driving circuit 902 drive the three-wavelength semiconductor laser device 700.

The optical pickup device 850 applies a laser beams controlled in response to the signal S3 to the optical disk 835, as shown in FIG. 26. From a light detection portion 830 in the optical pickup device 850, a signal S4 is outputted toward the signal generation circuit 903. Further, an optical system 820 (an actuator for a beam expander 823 and an objective lens actuator driving an objective lens 825) in the optical pickup device 850 is controlled by a servo signal S8 from the servo circuit 904 described later. The signal generation circuit 903 amplifies and processed arithmetically the signal S4 outputted from the optical pickup device 850, outputs a first output signal S5 including the playback signal toward the controller 901, and outputs a second output signal S6 performing feedback control of the optical pickup device 850 and rotation control of the optical disk 835 described later toward the servo circuit 904.

The servo circuit 904 outputs a servo signal S8 controlling the optical system 820 in the optical pickup device 850 and a motor servo signal S9 controlling the disk driving motor 905 in response to the second output signal S6 and the signal S7 from the signal generation circuit 903 and the controller 901, as shown in FIG. 26. Further, the disk driving motor 905 controls the rotational speed of the optical disk 835 in response to the motor servo signal S9.

In a case of playing back information recorded in the optical disk 835, a laser beam of wavelengths to be applied is first selected by a means identifying the type (a CD, a DVD, a BD or the like) of the optical disk 835 whose description is omitted here. Then, the signal S2 is outputted from the controller 901 toward the laser driving circuit 902 so that intensity of the laser beams of the wavelengths to be emitted from the three-wavelength semiconductor laser device 700 in the optical pickup device 850 is constant. Further, the three-wavelength semiconductor laser device 700, the optical system 720 and the light detection portion 830 of the optical pickup device 850 function, whereby the signal S4 including the playback signal is outputted from the light detection portion 830 toward the signal generation circuit 903 and the signal generation circuit 903 outputs the signal S5 including the playback signal toward the controller 901. The controller 901 extracts the playback signal having been recorded in the optical disk 835 by processing the signal S5, and outputs the playback signal as playback data S10. By this playback data S10, information such as images and sounds recorded in the optical disk 835 can be outputted to a monitor or a speaker, for example. The controller 901 also performs feedback control of the each portions on the basis of the signal S4 from the light detection portion 830.

In a case of recording information in the optical disk 835, a laser beam of wavelength to be applied is first selected by the means identifying the type (a CD, a DVD, a BD or the like) of the optical disk 835. Then, the signal S2 is outputted from the controller 901 toward the laser driving circuit 902 in response to the record data S1 responsive to the recorded information. Further, the three-wavelength semiconductor laser device 700, the optical system 820 and the light detection portion 830 of the optical pickup device 850 so function as to record the information in the optical disk 835 and as to perform feedback control of the each portion on the basis of the signal S4 from the light detection portion 830.

Thus, recording in and playback from the optical disk 835 can be performed by the optical disk device 900.

The optical disk device 900 includes the optical pickup device 850 in the eighth embodiment, whereby the optical disk device 900 having high reliability capable of withstanding long-time use, in which the individual semiconductor laser elements loaded on the optical pickup device 850 are inhibited from deterioration, can be obtained due to excellent heat radiation properties possessed by the three-wavelength semiconductor laser device 700. In addition, the optical disk device 900 in which the size of the optical pickup device 850 is inhibited from enlargement can be obtained.

### Tenth Embodiment

The structure of a projector device 950 according to a tenth embodiment of the present invention is described with reference to FIGS. 23, 27 and 28. In the projector device 950, such an example that individual semiconductor laser elements constituting an RGB three-wavelength semiconductor laser device 910 are substantially simultaneously turned on is described. The RGB three-wavelength semiconductor laser device 910 is an example of the “semiconductor light-emitting device” in the present invention, and the projector device 950 is an example of the “optical device” in the present invention.

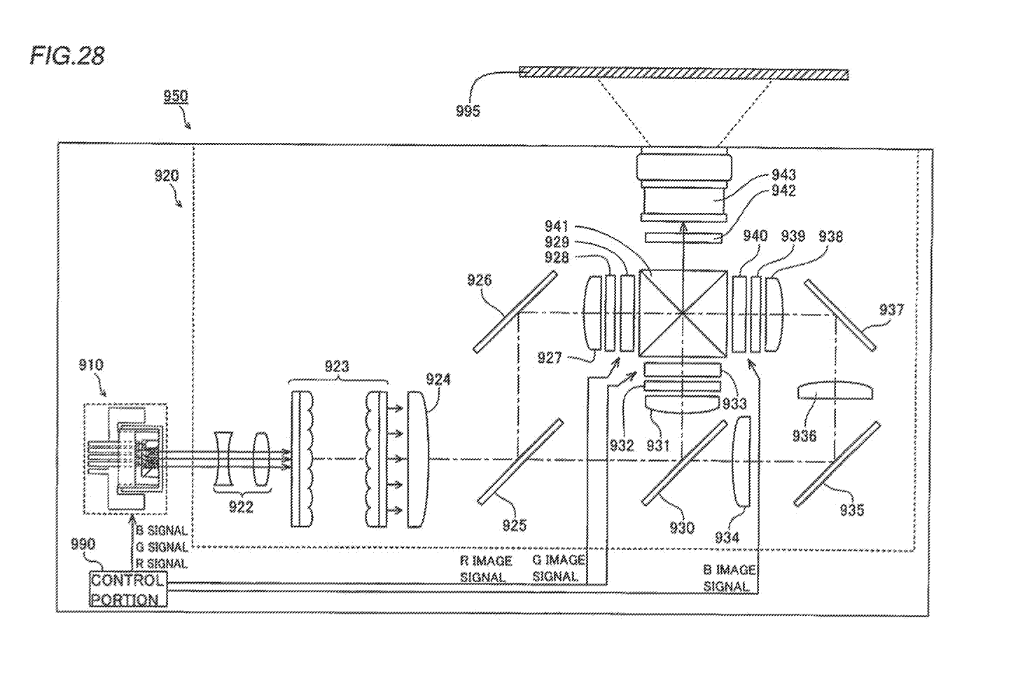

The projector device 950 includes the RGB three-wavelength semiconductor laser device 910, an optical system 920 consisting of a plurality of optical components, and a control portion 990 controlling the RGB three-wavelength semiconductor laser device 910 and the optical system 920, as shown in FIG. 28. Thus, laser beams emitted from the RGB three-wavelength semiconductor laser device 910 are modulated by the optical system 920, and thereafter projected on an external screen 995 or the like.

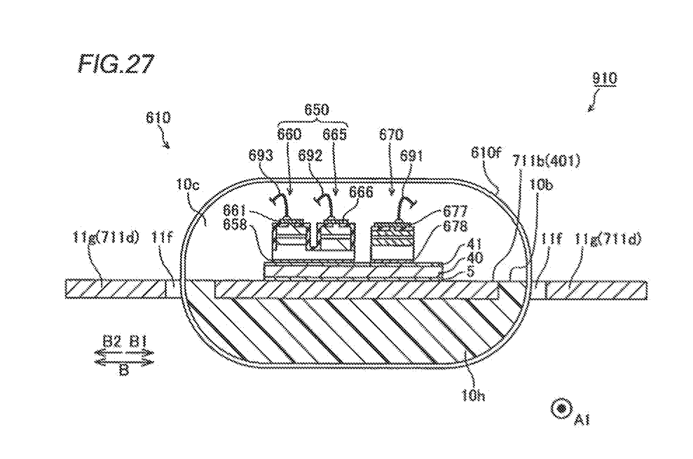

The RGB three-wavelength semiconductor laser device 910 includes the RGB three-wavelength semiconductor laser device 910 capable of emitting laser beams having RGB three wavelengths in which a red semiconductor laser element 650 having a red (R) lasing wavelength of about 655 nm is bonded to a two-wavelength semiconductor laser element 650 in which a green semiconductor laser element 660 having a green (G) lasing wavelength of about 530 nm and a blue semiconductor laser element 665 having a blue (B) wavelength of about 480 nm are monolithically formed, as shown in FIG. 27.

Referring to the three-wavelength semiconductor laser device 705 according to the modification of the seventh embodiment shown in FIG. 24, the RGB three-wavelength semiconductor laser device 910 includes the red semiconductor laser element 670 (see FIG. 27) formed on the upper surface of an n-type GaAs substrate 71 in place of the blue-violet semiconductor laser element 20, and includes the two-wavelength semiconductor laser element 650 (see FIG. 27) in which the green semiconductor laser element 660 and the blue semiconductor laser element 665 are monolithically formed on the lower surface of the n-type GaN substrate 21 in place of the two-wavelength semiconductor laser element 60 in which the red semiconductor laser element 70 and the infrared semiconductor laser element 80 are monolithically formed. Each semiconductor laser elements is bonded onto the surface of a submount 740 through a pad electrode 741.

As shown in FIG. 27, the red semiconductor laser element 670 is connected to a front end region 714b (see FIG. 24) of a lead terminal 714 through a metal wire 791 wire-bonded to a p-side electrode 77. The blue semiconductor laser element 665 is connected to a front end region 713b (see FIG. 24) of a lead terminal 713 through a metal wire 792 wire-bonded to a p-side pad electrode 666. The green semiconductor laser element 660 is connected to a front end region 712b (see FIG. 24) of a lead terminal 712 through a metal wire 793 wire-bonded to a p-side pad electrode 661. A monitoring PD 742 formed to be capable of receiving laser beams from light-reflecting surfaces of the respective laser elements is connected to a front end region 715b (see FIG. 24) of a lead terminal 715 through a metal wire 794 wire-bonded to a p-type region 742b (see FIG. 23). An n-side electrode 678 of the red semiconductor laser element 670, an n-side electrode 658 of the two-wavelength semiconductor laser element 650 and an n-type region (not shown) of the monitoring PD 742 are electrically connected to the lead terminal 711 through the submount 740 together, whereby common cathode wire connection is implemented in the RGB three-wavelength semiconductor laser device 910.

The remaining structure of and a manufacturing process for the RGB three-wavelength semiconductor laser device 910 are similar to those of the case of the three-wavelength semiconductor laser device 700 according to the seventh embodiment.

In the optical system 920, the laser beams emitted from the RGB three-wavelength semiconductor laser device 910 are converted to parallel beams having prescribed beam diameters by a dispersion angle control lens 922 consisting of a concave lens and a convex lens and thereafter introduced into a fly-eye integrator 923, as shown in FIG. 28. In the fly-eye integrator 923, two fly-eye lenses consisting of fly-eye lens groups face each other, and give lens action to light introduced from the dispersion angle control lens 922 so that light-intensity distribution incident upon liquid crystal panels 929, 933 and 940 is uniform. In other words, light transmitted through the fly-eye integrator 923 is adjusted to be introducible with spreading in an aspect ratio (16:9, for example) corresponding to the sizes of the liquid crystal panels 929, 933 and 940.

The light transmitted through the fly-eye integrator 923 is condensed by a condenser lens 924. In the light transmitted through the condenser lens 924, only red light is reflected by a dichroic mirror 925, while green light and blue light are transmitted through the dichroic mirror 925.

The red light is introduced into the liquid panel 929 through an incidence-side polarizing plate 928 after parallelization by a lens 927 through a mirror 926. This liquid crystal panel 929 is driven in response to a red image signal (R image signal) thereby modulating the red light.

Only the green light in the light transmitted through the dichroic mirror 925 is reflected by a dichroic mirror 930, while the blue light is transmitted through the dichroic mirror 930.

Then, the green light is introduced into the liquid crystal panel 933 through an incidence-side polarizing plate 932 after parallelization by a lens 931. This liquid crystal panel 933 is driven in response to a green image signal (G image signal) thereby modulating the green light.

The blue light transmitted through the dichroic mirror 930 is introduced into the liquid crystal panel 940 through an incidence-side polarizing plate 939 after parallelization is further performed by a lens 938 through a lens 934, a mirror 935, a lens 936 and a mirror 937. This liquid crystal panel 940 is driven in response to a blue image signal (B image signal) thereby modulating the blue light.

Thereafter the red light, the green light and the blue light modulated by the liquid crystal panels 929, 933 and 940 are synthesized by a dichroic prism 941, and thereafter introduced into a projection lens 943 through an emission-side polarizing plate 942. The projection lens 943 stores a lens group for imaging projected light on a projected surface (screen 995) and an actuator for adjusting zooming and focusing of projected images by displacing part of the lens group in an optical axis direction.

In the projector device 950, stationary voltages as an R signal related to driving of the red semiconductor laser element 670, a G signal related to driving of the green semiconductor laser element 660 and a B signal related to driving of the blue semiconductor laser element 665 are controlled by a control portion 990 to be supplied to the respective laser elements of the RGB three-wavelength semiconductor laser device 910. Thus, the red semiconductor laser element 670, the green semiconductor laser element 660 and the blue semiconductor laser element 665 of the RGB three-wavelength semiconductor laser device 910 substantially simultaneously lase. Further, hues, brightness etc. of pixels projected on the screen 995 are controlled by controlling each intensity of the light of the red semiconductor laser element 670, the green semiconductor laser element 660 and the blue semiconductor laser element 665 by the control portion 990. Thus, desired images are projected on the screen 990 by the control portion 990.

Thus, the projector device 950 loaded with the RGB three-wavelength semiconductor laser device 910 is constituted.

### Eleventh Embodiment

The structure of a projector device 980 according to an eleventh embodiment of the present invention is described with reference to FIGS. 27, 29 and 30. In the projector device 980, such an example that individual semiconductor laser elements constituting an RGB three-semiconductor laser device 910 are turned on in a time-series manner is described. The projector device 980 is an example of the “optical device” in the present invention.

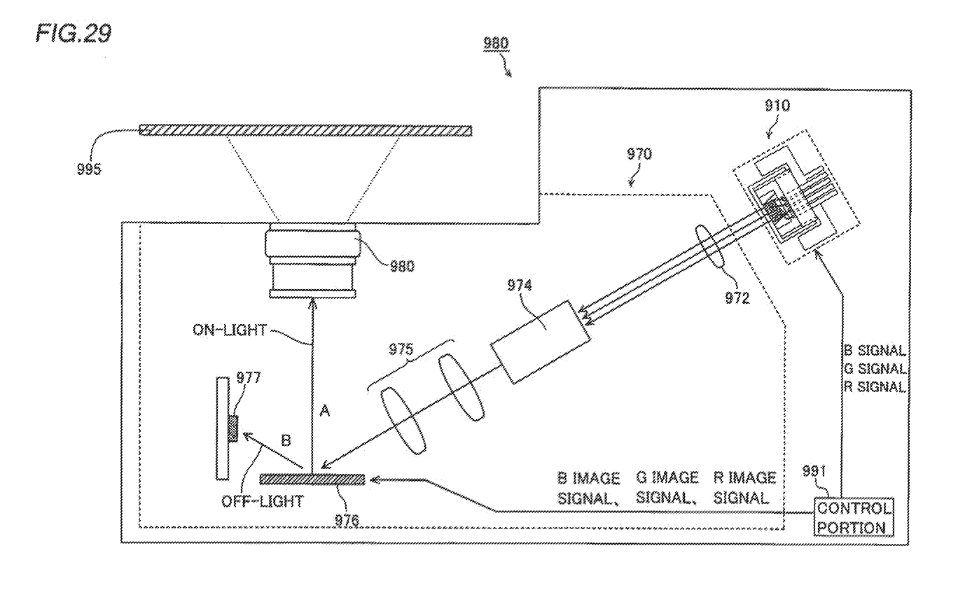

The projector device 980 includes the RGB three-wavelength semiconductor laser device 910 employed in the tenth embodiment, an optical system 970 and a control portion 911 controlling the RGB three-wavelength semiconductor laser device 910 and the optical system 970, as shown in FIG. 29. Thus, laser beams from the RGB three-wavelength semiconductor laser device 910 are modulated by the optical system 970, and thereafter projected on a screen 995 or the like.

In the optical system 970, each laser beam emitted from the RGB three-wavelength semiconductor laser device 910 is converted to a parallel beam by a lens 972, and thereafter introduced into a light pipe 974.

The inner surface of the light pipe 974 is a mirror surface, and the laser beams advance in the light pipe 974 while repeating reflection on the inner surface of the light pipe 974. At this time, intensity distribution of the laser beams of individual colors emitted from the light pipe 974 is uniformized due to multiple reflection action in the light pipe 974. The laser beams emitted from the light pipe 974 are introduced into a digital micromirror device (DMD) 976 through a relay optical system 975.

The DMD 976 consists of a small mirror group arranged in a matrix shape. The DMD 976 has a function of expressing (modulating) gradations of individual pixels by switching light reflection directions on the respective pixel positions to a first direction A directed toward a projection lens 980 and a second direction B deviating from the projection lens 980. Among the laser beams incident upon the individual pixel positions, light (ON-light) reflected in the first direction A is introduced into the projection lens 980 and projected on the projected surface (screen 995). Light (OFF-light) reflected by the DMD 976 in the second direction B is not introduced into the projection lens 980 but absorbed by a light absorber 977.

In the projector device 980, a pulse power source is controlled by the control portion 991 so as to be supplied to the RGB three-wavelength semiconductor laser device 910, whereby the red semiconductor laser element 670, the green semiconductor laser element 660 and the blue semiconductor laser element 665 of the RGB three-wavelength semiconductor laser device 910 are set and to be periodically driven one by one in a time sharing manner. Due to the control portion 991, the DMD 976 of the optical system 970 modulates light in response to the gradations of the individual pixels (R, G and B) while synchronizing with each operation state of the red semiconductor laser element 670, the green semiconductor laser element 660 and the blue semiconductor laser element 665.

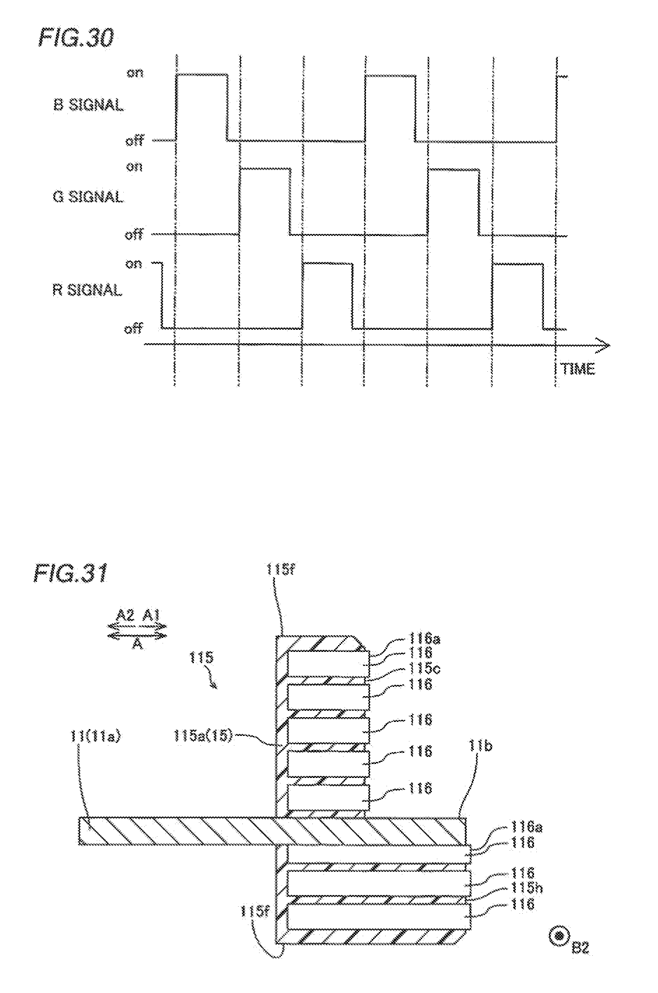

More specifically, an R signal related to operation of the red semiconductor laser element 670 (see FIG. 27), a G signal related to operation of the green semiconductor laser element 660 (see FIG. 27) and a B signal related to driving of the blue semiconductor laser element 665 (see FIG. 27) are supplied to the respective laser elements of the RGB three-wavelength semiconductor laser device 910 by the control portion 991 (see FIG. 29) in a time-sharing manner not to overlap with each other, as shown in FIG. 30. In synchronization with this B signal, the G signal and the R signal, a B image signal, a G image signal and an R image signal are outputted from the control portion 991 to the DMD 976 respectively.

Thus, blue light of the blue semiconductor laser element 665 is emitted on the basis of the B signal in a timing chart shown in FIG. 30, while the blue light is modulated by the DMD 976 on the basis of the B image signal at this timing. Further, green light of the green semiconductor laser element 660 is emitted on the basis of the G signal outputted subsequently to the B signal, while the green light is modulated by the DMD 976 on the basis of the G image signal at this timing. In addition, red light of the red semiconductor laser element 670 is emitted on the basis of the R signal outputted subsequently to the G signal, while the red light is modulated by the DMD 976 on the basis of the R image signal at this timing. Thereafter the blue light of the blue semiconductor laser element 665 is emitted on the basis of the B signal outputted subsequently to the R signal, while the blue light is modulated by the DMD 976 on the basis of the B image signal again at this timing. The aforementioned operations are so repeated that images by laser beam application based on the B image signal, the G image signal and the R image signal are projected on the projected surface (screen 995).

Thus, the projector device 980 loaded with the RGB three-wavelength semiconductor laser device 910 is constituted.

In the projector devices 950 and 980 in the tenth embodiment and the eleventh embodiment, the RGB three-wavelength semiconductor laser devices 910 (see FIG. 27) are packaged in the projector devices, whereby the projector devices 950 and 980 having high reliability capable of withstanding long-time use, in which the red semiconductor laser elements 670, the green semiconductor laser elements 660 and the blue semiconductor laser elements 665 are inhibited from deterioration, can be easily obtained due to excellent heat radiation characteristics possessed by the RGB three-semiconductor laser devices 910. In addition, the projector devices 950 and 980 in which the sizes of the RGB three-semiconductor laser devices 910 are inhibited from enlargement can be obtained.

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are further included.

For example, while the example of employing the resin material into which the gas absorbent is mixed for each of the base portion and the cap portion has been shown in each of the first to eleventh embodiments, the present invention is not restricted to this. In other words, a semiconductor laser device may be constituted of resin material into which gas absorbent is mixed for only a base portion while employing resin material into which no gas absorbent is mixed for a cap portion. Alternatively, a package of a semiconductor laser device may be constituted of resin material into which gas absorbent is mixed for only a cap portion while employing resin material into which no gas absorbent is mixed for a base portion.

While the example of employing the synthetic zeolite as the gas absorbent has been shown in each of the first to eleventh embodiments, the present invention is not restricted to this. In the present invention, particulate silica gel or activated carbon pulverized to have a particle diameter of at least several 10 μm and not more than several 100 μm may be employed as a gas absorbent, for example, and any one of synthetic zeolite, silica gel and activated carbon may be employed.

While the example of preparing the cap portion from silicone resin or thermoplastic fluororesin having elasticity and constituting the package of the semiconductor laser device by engaging the cap portion with the base portion has been shown in each of the first to eleventh embodiments, the present invention is not restricted to this. In the present invention, a base portion of a lead frame may be prepared from silicone resin, thermoplastic fluororesin or the like having elasticity, and a package of a semiconductor laser device may be constituted by engaging the base portion with a cap portion.

While the example of preparing the base portion and the cap portion both made of the mixtures of resin and the gas absorbents has been shown in each of the first to eleventh embodiments, the present invention is not restricted to this. In the present invention, one of a base portion and a cap portion may be formed by a metallic material, and the other one may be made of a mixture of resin and gas absorbent.

While the example of forming the base portion by uniformly mixing the particulately smashed gas absorbent (synthetic zeolite) into the resin (epoxy resin) has been shown in each of the first to eleventh embodiments, the present invention is not restricted to this. In the present invention, a plurality of pellets (cylinders) of gas absorbents 116 may be embedded into a base portion 115 and formed without smashing, as in a fourth modification of the first embodiment shown in FIG. 31. In this case, most portions of each pellet of gas absorbents 116 is embedded in resin 15 (epoxy resin or the like, for example), while first end portions 116a of the embedded plurality of pellets are exposed from a facet (front surface 115c) of the base portion 115. In the formation as this fourth modification, organic gas generated in the resin 15 is absorbed by the gas absorbents 116 embedded in the base portion 115, while organic gas leaking in a package is also absorbed by the first end portions 116a exposed on facets (front surfaces 115c and 115h) of the base portion 115. As compared with the internal structure of the base portion 10 shown in FIG. 2, the vicinity of an outer peripheral surface 115f of the base portion 115 has a region constituted of only the resin 15 with no presence of the gas absorbents 116, whereby low molecular siloxane from the exterior (in the atmosphere) and volatile organic gas can be inhibited from penetrating into the resin 15. A suppressing effect against external gas penetration can be further increased by forming a gas barrier layer on the outer peripheral surface 115f.

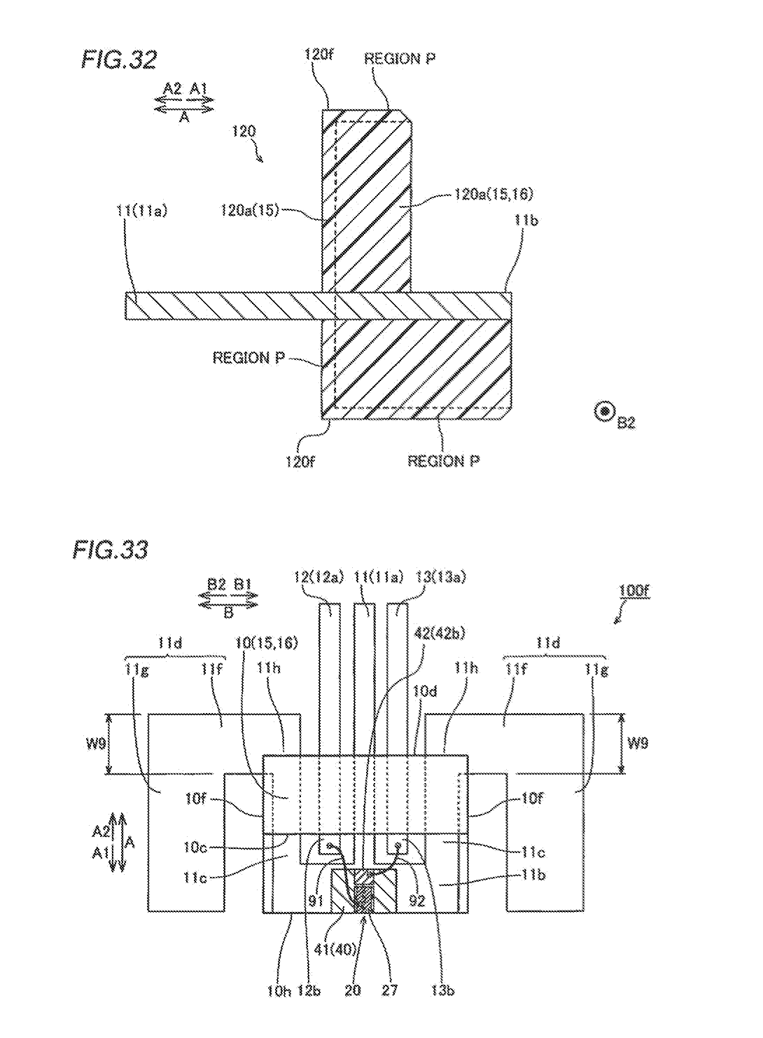

While the example of forming the base portion by uniformly mixing the particulately smashed gas absorbent (synthetic zeolite) into the resin (epoxy resin) has been shown in each of the first to eleventh embodiments, the present invention is not restricted to this. In the present invention, a base portion 120 may be molded to have a region P where no particulately smashed gas absorbent is mixed into epoxy resin in the vicinity of an outer peripheral surface 120f of the base portion 120, as in a fifth modification of the first embodiment shown in FIG. 32. Also when forming the base portion 120 as in this fifth modification, the vicinity of the outer peripheral surface 120f of the base portion 120 has the region P formed by only resin 15 with no presence of a gas absorbent as compared with the internal structure of the base portion 10 shown in FIG. 2, whereby low molecular siloxane from the exterior (in the atmosphere) and volatile organic gas are inhibited from penetrating into the resin 15. An effect of suppressing gas penetration from the exterior a package can be further increased by forming a gas barrier layer on the outer peripheral surface 120f similarly to the aforementioned first embodiment.

While the example of providing the gas barrier layers with for of the base portion and the cap portion has been shown in each of the first to eleventh embodiments, the present invention is not restricted to this. In other words, a gas barrier layer may be provided only for either a base portion or a cap portion in the present invention.

While the example of providing the gas barrier layer 17 for the outer surface of the base portion has been shown in each of the first to eleventh embodiments, the present invention is not restricted to this. In other words, a gas barrier layer may be provided for a surface (a front surface of a header portion and a front surface and an upper surface of a protruding block portion) of a base portion on a side in contact with a space in a package in the present invention. Similarly, a gas barrier layer may be provided for a surface (inner surface of a cap portion) of the cap portion on a side in contact with a space in a package, also as to the cap portion.

While the example in which the gas barrier layers are made of SiO₂ has been shown in each of the first to eleventh embodiments, the present invention is not restricted to this. For example, gas barrier layers may be formed by dielectric films of Al₂O₃, ZrO₂ or the like. In a case where a multilayer metal-oxide film of Al₂O₃, ZrO₂ or the like constitutes a gas barrier layer 33 formed on a cap portion, this metal-oxide film serving also as the gas barrier layer 33 has a role of an antireflection layer. In the case where the metal oxide film as the antireflection layer constitutes the gas barrier layer 33, the same is preferably formed on both surfaces of the inner surface and the outer surface of the light transmission portion 35 of the cap portion 30 shown in FIG. 2.

While each of the first to eleventh embodiments has shown the example where the base portion and the cap portion in which the gas absorbent are mixed into the resin constitutes the package, the present invention is not restricted to this. In the present invention, gas absorbent may be set in a vacant space in the package, in addition to the base portion and the cap portion in which the gas absorbents are mixed into the resin.

While the example in which the first heat radiation portions 11f in the heat radiation portions 11d extend outward from positions slightly rearward beyond the rear surface 10d of the base portion 10 has been shown in the first embodiment, the present invention is not restricted to this. In the present invention, parts (front end sides) of first heat radiation portions 11f may protrude and extend outward (on a B2 side or on a B1 side) from an outer peripheral surface 10f of a base portion 10, as in a semiconductor laser device 100f according to a sixth modification shown in FIG. 33. In this case, the width of the first heat radiation portions 11f is W9 (W9>W3 (see FIG. 4)). In the present invention, further, the first heat radiation portions 11f may not be exposed rearward from the rear surface 10d, but all parts may pass through the outer peripheral surface 10f in the lateral direction (direction B) from inside the base portion 10 to extend outward. In this case, a cap portion 30 can be engaged as in the aforementioned first embodiment, by leaving a region where no heat radiation portions are formed on a front side of the outer peripheral surface 10f of the base portion 10. Thus, a blue-violet semiconductor laser element 20 can be sealed.

While the example of bending the first heat radiation portions 211f upward (direction C2 in FIG. 11) has been shown in the second embodiment, heat radiation portions 11d may be formed by bending first heat radiation portions 211f downward (direction C1) in the present invention.

While the example of bending the end portions of the connection portions 311c upward (direction C2 in FIG. 13) has been shown in the third embodiment, connection portions may be formed by bending end regions of connection portions 311c downward (direction C1) in the present invention.

While the heat radiation portions have been extended upward by bending the connection portions in the second embodiment, the heat radiation portions may be bent so that the heat radiation portions are extended in the bent direction.

While the example of laterally aligning and arranging the lead terminals 712 to 715 on the same plane on the surface of the lead frame (plane portion 401) having the lead terminal 711 has been shown in the modification of the seventh embodiment, lead terminals 714 and 715 may be further stacked on lead terminals 712 and 713 in the present invention, for example. Thus, a plurality of lead terminals are not arranged to spread in the width direction of a semiconductor laser device, whereby the width of a three-wavelength semiconductor laser device can be reduced.

While the example in which the protruding block portion 10b protruding frontward is formed on the base portion 10 has been shown in each of the aforementioned embodiments, the base portion 10 may have a substantially discoidal shape in which no protruding block portion 10b protrudes in the present invention.

While the example of sealing the package 50 by engaging the base portion with the cap portion has been shown in each of the first to eleventh embodiments, the present invention is not restricted to this. As a reference example, a semiconductor laser device may be constituted without putting a cap portion on a base portion.

1. A semiconductor light-emitting device comprising:
a semiconductor light-emitting element; and
a package sealing said semiconductor light-emitting element, wherein
said package includes a base portion mounted with said semiconductor light-emitting element and a cap portion mounted on said base portion for covering said semiconductor light-emitting element, and
at least either one of said base portion and said cap portion is made of a mixture of resin and gas absorbent.

2. The semiconductor light-emitting device according to claim 1, wherein
said cap portion has a light transmission portion, made of said mixture, through which light emitted from said semiconductor light-emitting element is transmitted toward the exterior,
said resin has translucency, and
said gas absorbent is mixed into said mixture constituting said cap portion other than said light transmission portion.

3. The semiconductor light-emitting device according to claim 1, wherein
said gas absorbent is at least any one of synthetic zeolite, silica gel and activated carbon.

4. The semiconductor light-emitting device according to claim 1, wherein
a gas barrier layer is formed on a surface of at least either one of said base portion and said cap portion made of said mixture.

5. The semiconductor light-emitting device according to claim 1, further comprising:
a plurality of lead terminals mounted on said base portion and arranged on an identical plane, and
a heat radiation portion formed integrally with an element placement portion on which said semiconductor light-emitting element is placed, wherein
said heat radiation portion is arranged outside said plurality of lead terminals.

6. The semiconductor light-emitting device according to claim 5, wherein
said heat radiation portion is arranged on said identical plane.

7. The semiconductor light-emitting device according to claim 5, wherein
said heat radiation portion and said element placement portion are connected with each other by a connection portion extending from a front surface side of said base portion, and
a connection region between said heat radiation portion and said connection portion is arranged on said rear surface side of said base portion.

8. The semiconductor light-emitting device according to claim 7, wherein
said connection region is at least partially exposed from said rear surface of said base portion.

9. The semiconductor light-emitting device according to claim 7, wherein
said heat radiation portion is arranged outside said cap portion.

10. The semiconductor light-emitting device according to claim 5, wherein
said heat radiation portion is arranged outside said plurality of lead terminals at least on a first side portion in both side portions of said base portion.

11. The semiconductor light-emitting device according to claim 5, wherein
said lead terminals include a first lead terminal mounted on a rear surface of said base portion, and
said element placement portion is formed integrally with said first lead terminal.

12. The semiconductor light-emitting device according to claim 5, wherein
said lead terminals include a second lead terminal mounted on a rear surface of said base portion, and
said element placement portion and said second lead terminal are arranged on respective planes different from each other.

13. The semiconductor light-emitting device according to claim 5, wherein
at least parts of said connection portion and said heat radiation portion are bent.

14. The semiconductor light-emitting device according to claim 13, wherein
at least parts of said connection portion and said heat radiation portion are bent in a direction parallel to a rear surface of said base portion.

15. The semiconductor light-emitting device according to claim 5, wherein
a width of said heat radiation portion is larger than a width of said lead terminals.

16. The semiconductor light-emitting device according to claim 1, wherein
said resin has elasticity, and
said base portion and said cap portion so engage with each other that said semiconductor light-emitting element is sealed.

17. The semiconductor light-emitting device according to claim 16, wherein
said base portion and said cap portion are both made of mixtures of said resin and said gas absorbent, and
a ratio of said gas absorbent mixed into said resin of said cap portion with respect to said resin of said cap portion is smaller than a ratio of said gas absorbent mixed into said resin of said base portion with respect to said resin of said base portion.

18. The semiconductor light-emitting device according to claim 16, wherein
said base portion has an outer peripheral surface tapering from a rear surface side of said base portion toward a front surface side of said base portion, and
said cap portion engages with tapering said outer peripheral surface of said base portion.

19. A method for manufacturing a semiconductor light-emitting device, comprising the steps of:
forming a base portion and a cap portion;
mounting a semiconductor light-emitting element on said base portion; and
sealing said semiconductor light-emitting element by engaging said base portion with said cap portion, wherein
the step of forming said base portion and said cap portion includes a step of forming at least either one of said base portion and said cap portion by molding a mixture of resin and a gas absorbent.

20. An optical device comprising:
a semiconductor light-emitting device including a semiconductor light-emitting element and a package sealing said semiconductor light-emitting element; and
an optical system controlling light emitted from said semiconductor light-emitting device, wherein
said package has a base portion mounted with said semiconductor light-emitting element and a cap portion mounted on said base portion for covering said semiconductor light-emitting element, and
at least either one of said base portion and said cap portion is made of a mixture of resin and a gas absorbent.
